(19) United States
(12) Patent Application Publication
(10) Pub. No.: US 2026/0113043 A1
(43) Pub. Date: Apr. 23, 2026

(54) METHODS AND APPARATUS TO MAINTAIN A PHASE LOCK DURING A FREQUENCY CHANGE

(71) Applicant: Texas Instruments Incorporated, Dallas, TX (US)

(72) Inventors: Saikiran Kurba, Bengaluru (IN); Abhijit Anant Patki, Bangalore (IN); Atul Kumar Agrawal, Bangalore (IN); Karan Das, Hajo (IN)

(21) Appl. No.: 19/223,891

(22) Filed: May 30, 2025

(30) Foreign Application Priority Data
Oct. 23, 2024 (IN) 202441080776

(51) Int. Cl. H03L 7/099; G06F 3/16; H03K 3/037; H03L 7/085; H04R 3/00

(52) U.S. Cl. CPC H03L 7/099; G06F 3/162; H03K 3/037; H03L 7/085; H04R 3/00

(57) ABSTRACT

In an embodiment, a device includes: phase frequency detector (PFD) circuitry having an input and an output; an oscillator having an input and an output, the input of the oscillator coupled to the output of the PFD circuitry; clock divider circuitry having a first input, a second input, and an output, the first input of the clock divider circuitry coupled to the output of the oscillator, the output of the clock divider circuitry coupled to the input of the PFD circuitry; and a controller having an output coupled to the second input of the clock divider circuitry.

### CROSS-REFERENCE TO RELATED APPLICATION

This patent application claims the benefit of and priority to Indian Provisional Patent Application No. 202441080776 filed Oct. 23, 2024, which is hereby incorporated herein by reference in its entirety.

### TECHNICAL FIELD

This description relates generally to an electronic system and method, and, in particular embodiments, to methods and apparatus to maintain a phase lock during a frequency change.

### BACKGROUND

Communication systems typically use a clock signal to exchange data. Some communication systems designate a primary device to provide the clock signal. The clock signal is associated with the timing of data of a data stream between the primary and secondary devices. The primary device sets the frequency of the clock signal to match the data rate of the data stream. The secondary device captures data of the data stream using the clock signal.

### SUMMARY

In accordance to an embodiment, a device includes: phase frequency detector (PFD) circuitry having an input and an output; an oscillator having an input and an output, the input of the oscillator coupled to the output of the PFD circuitry; clock divider circuitry having a first input, a second input, and an output, the first input of the clock divider circuitry coupled to the output of the oscillator, the output of the clock divider circuitry coupled to the input of the PFD circuitry; and a controller having an output coupled to the second input of the clock divider circuitry.

In accordance to an embodiment, a device includes: phase frequency detector (PFD) circuitry; an oscillator coupled to the PFD circuitry; clock divider circuitry having an output coupled to the PFD circuitry, and an input coupled to the oscillator; and a controller coupled to the clock divider circuitry, and configured to adjust the clock divider circuitry responsive to a change in a reference clock.

In accordance to an embodiment, a method includes: generating phase lock loop (PLL) clock based on a phase error between a reference clock and a feedback clock; dividing the PLL clock to generate the feedback clock; and adjusting a phase of the feedback clock responsive to a change in a frequency of the reference clock.

In accordance to an embodiment, a method includes: generating phase lock loop (PLL) clock based on a phase error between a reference clock and a feedback clock; dividing the PLL clock to generate the feedback clock; and adjusting the feedback clock responsive to a change in a frequency of the reference clock to maintain a switching frequency and phase of the PLL clock.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an example audio system including example phase lock loop (PLL) circuitry;

FIG. 2 is a block diagram of an example of the PLL circuitry of FIG. 1 including an example controller to maintain a phase lock during a frequency change;

FIG. 3 is a block diagram of an example of the PLL circuitry of FIGS. 1 and 2 including an example of the controller of FIG. 2, which aligns a feedback clock to maintain a phase lock during a frequency change;

FIG. 4 is a timing diagram of example signals of the controller of FIG. 3 or, more generally, the PLL circuitry of FIGS. 1, 2, and 3;

FIG. 5 is a flowchart representative of example machine-readable instructions or example operations that may be at least one of executed, instantiated, or performed using an example implementation of the controller of FIGS. 2 and 3 or, more generally, the PLL circuitry of FIGS. 1, 2, and 3;

FIG. 6 is a timing diagram of example operations of the PLL circuitry of FIGS. 1, 2, and 3 during an example frequency change;

FIG. 7 is a block diagram of an example of the PLL circuitry of FIGS. 1, 2, and 3 including another example of the controller of FIGS. 2 and 3, which resets generation of a feedback clock to maintain a phase lock during a frequency change;

FIG. 8 is a timing diagram of example signals of the controller of FIG. 7 or more generally the PLL circuitry of FIGS. 1, 2, and 7;

FIG. 9 is a flowchart representative of example machine-readable instructions or example operations that may be at least one of executed, instantiated, or performed using an example implementation of the controller of FIGS. 2 and 7 or, more generally, the PLL circuitry of FIGS. 1, 2, and 7;

FIG. 10 is a timing diagram of example operations of the PLL circuitry of FIGS. 1, 2, and 7 during an example frequency change;

FIG. 11 is a block diagram of an example processing platform including programmable circuitry structured to execute, instantiate, or perform the example machine-readable instructions or perform the example operations of FIGS. 5 and 9 to implement the PLL circuitry of FIGS. 1, 2, 3, and 7;

FIG. 12 is a block diagram of an example implementation of the programmable circuitry of FIG. 11; and

FIG. 13 is a block diagram of another example implementation of the programmable circuitry of FIG. 11.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Communication systems may use a clock signal to exchange data. Some communication systems designate a primary device (also referred to as a host device) to provide the clock signal. The clock signal may be associated with the timing of data of a data stream between the primary and secondary devices. In some communication systems, the primary device sets the frequency of the clock signal to match the data rate of the data stream, and the secondary device captures data of the data stream using the clock signal. In some communication systems, the secondary device uses the clock signal to drive additional operations, such as a digital-to-analog converter (DAC), upscaling, etc.

Communication protocols, such as MIPI SoundWire, support a range of frequencies of a host clock (SW_CLK). The host clock (SW_CLK) is a periodic clock signal having a frequency set to match the data rate of a data stream between devices. To use the host clock (SW_CLK) reliably, some devices include phase lock loop (PLL) circuitry (also referred to as phase-locked loop circuitry). The PLL circuitry produces a phase lock loop clock (PLL_CLK) of a set frequency using the host clock (SW_CLK).

Some PLL circuitry includes first divider circuitry, phase frequency detector (PFD) circuitry, a voltage-controller oscillator (VCO), and second divider circuitry. The first divider circuitry divides the host clock (SW_CLK) by a first PLL scalar value (J) to produce a reference clock (REF_CLK). The second divider circuitry divides the PLL clock (PLL_CLK) by a second PLL scalar value (D) to produce a feedback clock (FB_CLK). The PFD circuitry compares the phases of the reference clock (REF_CLK) and the feedback clock (FB_CLK). The VCO produces the PLL clock (PLL_CLK) having a frequency based on the determined phase difference. The PFD circuitry, the VCO, and the second divider circuitry form a feedback loop that produces the feedback clock (FB_CLK).

In example operations, the VCO modifies the frequency of the PLL clock (PLL_CLK) responsive to a phase difference between the reference clock (REF_CLK) and the feedback clock (FB_CLK). The PFD circuitry adjusts the VCO to align the phase of the feedback clock (FB_CLK) with the reference clock (REF_CLK). In a stable operating condition, also referred to as phase lock or a phase-locked loop, the frequency of the PLL clock (PLL_CLK) aligns the phase of the reference clock (REF_CLK) and the feedback clock (FB_CLK). The frequency of the PLL clock (PLL_CLK) remains constant in the stable operating condition. After establishing a phase lock, the PLL circuitry continues to produce the PLL clock with a stable frequency until the PFD circuitry detects a phase difference.

In some systems, a change in the frequency of the host clock (SW_CLK) may change the phase of the reference clock (REF_CLK). A sudden change in the phase of the reference clock (REF_CLK) may destabilize the operation of the PLL circuitry and create a transient period until the PFD circuitry and the VCO achieve another phase lock. During the transient period, between the lock states, the frequency of the PLL clock (PLL_CLK) can rapidly change.

In some devices, the changes in frequency of the PLL clock (PLL_CLK) during the transient period reduces reliability. For example, an audio amplifier using the PLL clock (PLL_CLK) to drive a digital-to-analog converter (DAC) may produce distorted audio during the periods between phase lock states.

Some communication protocols, such as SoundWire, have begun to include support for on-the-fly frequency changes of the host clock (SW_CLK). An on-the-fly change occurs when the frequency of the host clock (SW_CLK) changes during uninterrupted communications. As changes in the frequency of the host clock (SW_CLK) become increasingly popular, it may be advantageous to increase the immunity of PLL circuitry to frequency changes.

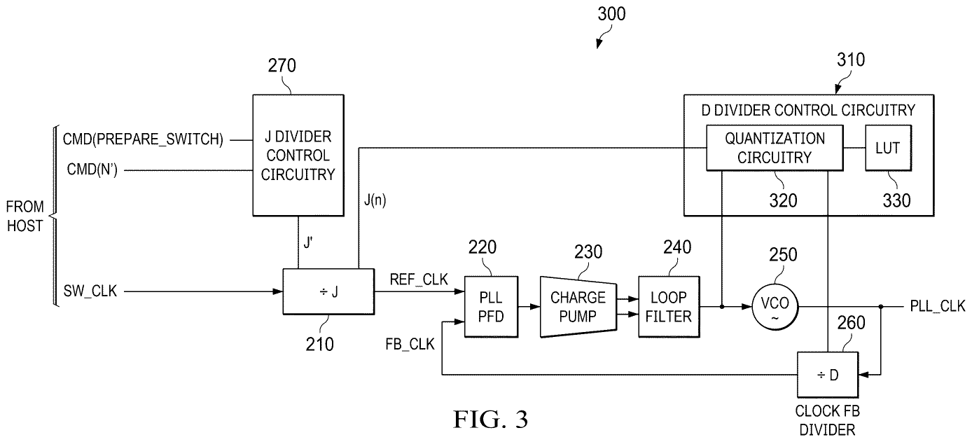

Examples described herein include methods and apparatus to maintain a phase lock during a frequency change. In some described examples, the PLL circuitry includes controllers to maintain a phase lock during a change in frequency of the host clock (SW_CLK). In some examples, e.g., as further illustrated in connection with FIGS. 3, 4, 5, and 6, the controllers implement a loop-aware locking mechanism. In some such examples, the controller adjusts the generation of a subsequent edge of the feedback clock (FB_CLK) based on the frequency of the PLL clock (PLL_CLK), the original frequency of the host clock (SW_CLK), and the state of the first divider circuitry. For example, the controller determines a period remaining before the next edge of the reference clock (REF_CLK), as if the frequency of the host clock (SW_CLK) were not changing. In such examples, the controller adjusts the second divider circuitry by the determined period to align the feedback clock with the updated reference clock. In some embodiments, such a determination and adjustment may advantageously allow the PLL circuitry to maintain a phase lock despite a change in the host clock (SW_CLK).

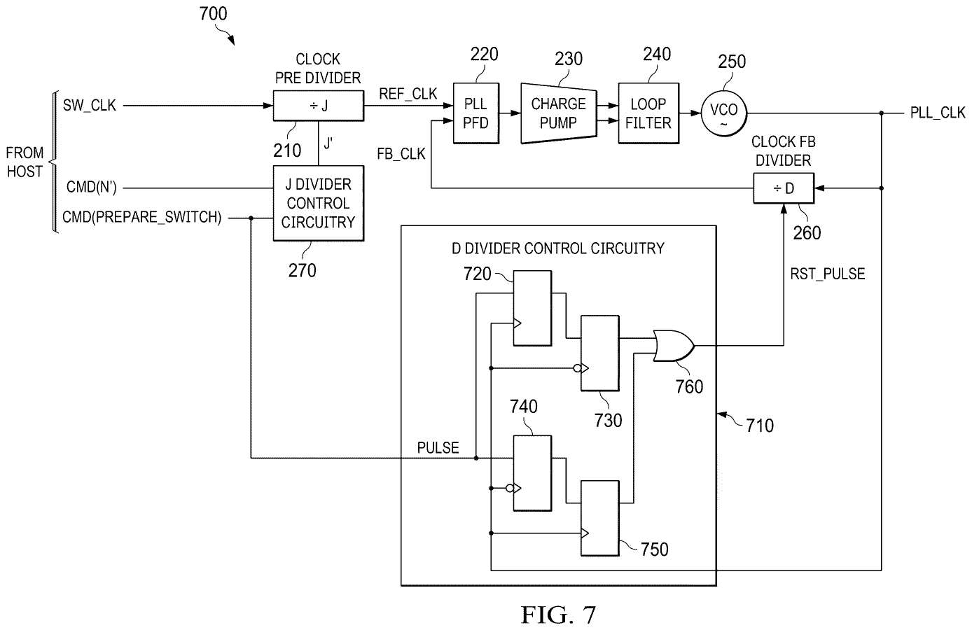

In some examples, e.g., as further illustrated in connection with FIGS. 7, 8, 9, and 10, the controller implements a brute force locking mechanism. In some such examples, the primary device provides a frequency switch prepare pulse prior to the frequency change. The controller latches the frequency switch prepare pulse using the PLL clock (PLL_CLK). The controller resets the second divider circuitry using the latched pulse (also referred to as a reset pulsc). The second divider circuitry produces a rising edge of the feedback clock (FB_CLK) responsive to the reset. In some embodiments, aligning the reset of the second divider circuitry and the frequency change of the host clock (SW_CLK) may advantageously reduce phase error. In some embodiments, reducing phase error during a change in frequency may advantageously increase the likelihood of the PLL circuitry maintaining phase lock.

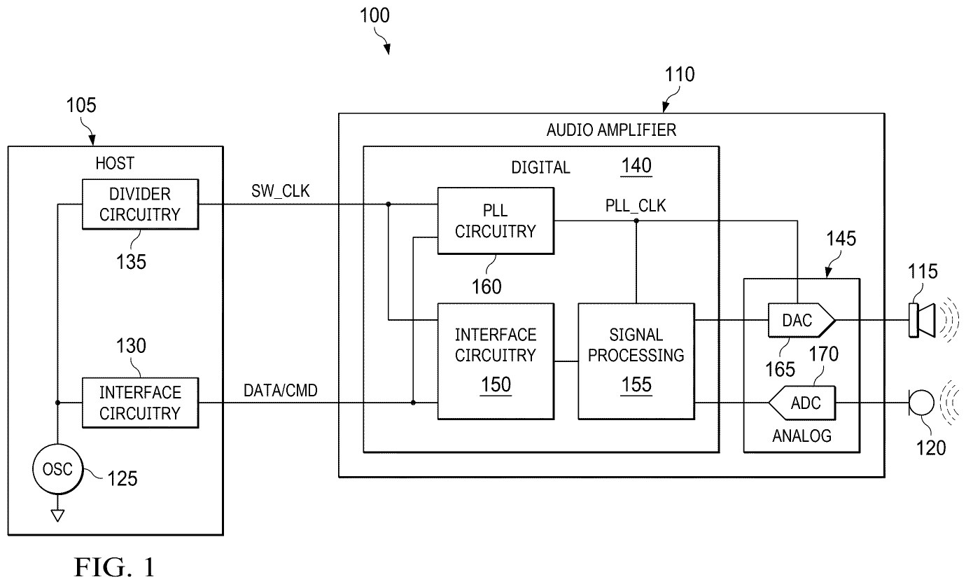

FIG. 1 is a block diagram of an example audio system 100, according to an embodiment of the present disclosure. In the example of FIG. 1, the audio system 100 includes a host device 105, audio amplifier circuitry 110, a speaker 115, and a microphone 120. In some examples, the audio system 100 is implemented as a part of the same integrated circuitry (IC) or as different parts of a multi-chip module (MCM). In such examples, the speaker 115 and microphone 120 may be coupled to the IC or MCM. In some embodiments, system 100 may be implemented with multiple discrete components. Other implementations are also possible.

In the example of FIG. 1, the host device 105 is an audio source, which provides digital audio signals to the amplifier circuitry 110. In some examples, the host device 105 may be a programmable device configurable to digitally interface with another device. The example host device 105 of FIG. 1 includes oscillator 125, interface circuitry 130, and divider circuitry 135. The host device 105 is communicatively coupled to the audio amplifier circuitry 110. In some examples, the host device 105 and the audio amplifier circuitry 110 exchange data using the MIPI SoundWire protocol. In such examples, the host device 105 provides a host clock (SW_CLK) and a data stream (DATA/CMD). Alternatively, the host device 105 and the audio amplifier circuitry 110 may implement an alternative communication protocol, such as inter-integrated circuit (I2C), improved inter-integrated circuitry (I3C), serial peripheral interface (SPI), etc.

The audio amplifier circuitry 110 of FIG. 1 includes digital circuitry 140 and analog circuitry 145. The audio amplifier circuitry 110 exchanges data with the host device 105 using the host clock (SW_CLK) and the data stream (DATA/CMD). In example operations, the host device 105 provides the audio amplifier circuitry 110 audio for playback using the data stream. In some examples, the audio amplifier circuitry 110 provides the host device 105 captured audio data for processing, storing, etc.

In example operations, the audio amplifier circuitry 110 receives commands (CMD) from the host device 105. In some examples, the host device 105 sequences a supply of commands via the data stream. In some such examples, the host device 105 sequences the supply of commands using the communication protocol. In some examples, the host device 105 provides the audio amplifier circuitry 110 commands using an additional interface. In some such examples, the additional interface implements an additional communication protocol, such as I2C, SPI, etc. In both examples, the host device 105 controls the audio amplifier circuitry 110 using commands.

The speaker 115 receives analog audio signals from the audio amplifier circuitry 110. The speaker 115 produces soundwaves responsive to the analog audio signals. In some examples, the speaker 115 produces audible sound, such as music. In other examples, the speaker 115 produces ultrasonic sound (e.g., sound having frequencies beyond the audible spectrum). In some such examples, the audio amplifier circuitry 110 may use the speaker 115 and microphone 120 for ultrasonic signaling, such as object detection.

The microphone 120 receives soundwaves from the surrounding environment. The microphone 120 produces analog audio signals responsive to receiving the soundwaves. In some examples, the microphone 120 captures audible sound, such as a user speaking. In some examples, the microphone 120 captures ultrasonic sound. The microphone 120 provides the analog audio signals to the audio amplifier circuitry 110.

The oscillator 125 produces a reference signal at a predetermined frequency. In some examples, one or more portions of the oscillator 125 may be external to the host device 105, such as an external crystal. The oscillator 125 provides the reference signal to the interface circuitry 130 and the divider circuitry 135.

The interface circuitry 130 interfaces with the audio amplifier circuitry 110 using the reference signal and a communication protocol. For example, the interface circuitry 130 uses SoundWire protocols to exchange data and commands with the audio amplifier circuitry 110. The interface circuitry 130 produces the data stream (DATA/CMD) using the communication protocol. In some examples, the interface circuitry 130 sequences data of the data stream using the reference signal from the oscillator 125. In some examples, the interface circuitry sequences data of the data stream using the host clock (SW_CLK) from the divider circuitry 135. The interface circuitry 130 provides data to and receives data from the audio amplifier circuitry 110 using the data stream (DATA/CMD).

The divider circuitry 135 divides the reference signal from the oscillator 125 by a scaling factor (N). The divider circuitry 135 provides the host clock (SW_CLK) to the audio amplifier circuitry 110. In some examples, such as if the interface circuitry 130 implements SoundWire protocols, the divider circuitry 135 changes the frequency of the host clock on-the-fly. In some such examples, the divider circuitry 135 modifies the scaling factor of the reference clock signal to produce the host clock (SW_CLK) at a new frequency.

The example digital circuitry 140 of FIG. 1 includes example interface circuitry 150, example signal processing circuitry 155, and example PLL circuitry 160. The digital circuitry 140 receives the host clock (SW_CLK) and the data stream (DATA/CMD) from the host device 105. In some example operations, the digital circuitry 140 receives a digital audio signal from the analog circuitry 145. In some such examples, the digital audio signal represents captured audio. Similar to the interface circuitry 130, the interface circuitry 150 (which may be a SoundWire interface) interfaces with the host device 105 using the host clock (e.g., SW_CLK) and a communication protocol. In some examples, the interface circuitry 130, 150 are communicatively coupled using a SoundWire protocol.

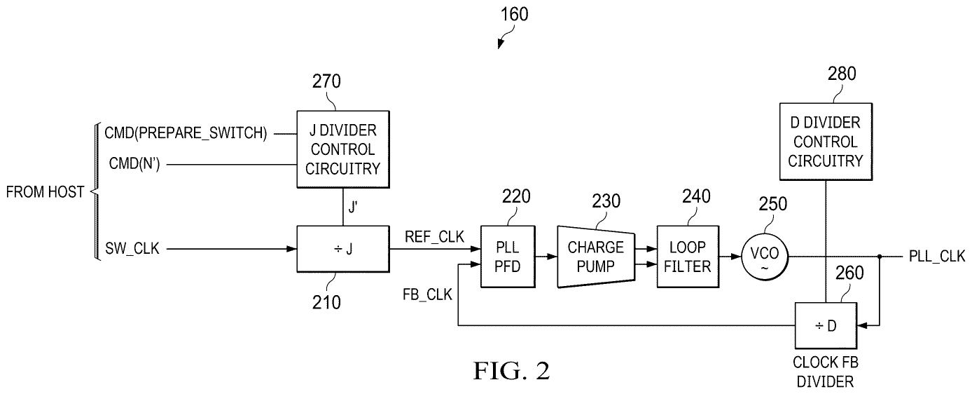

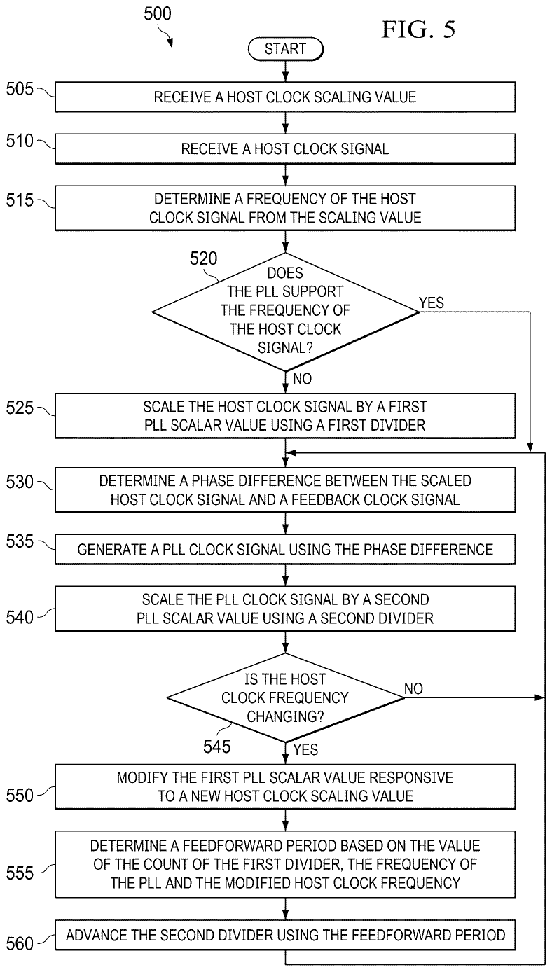

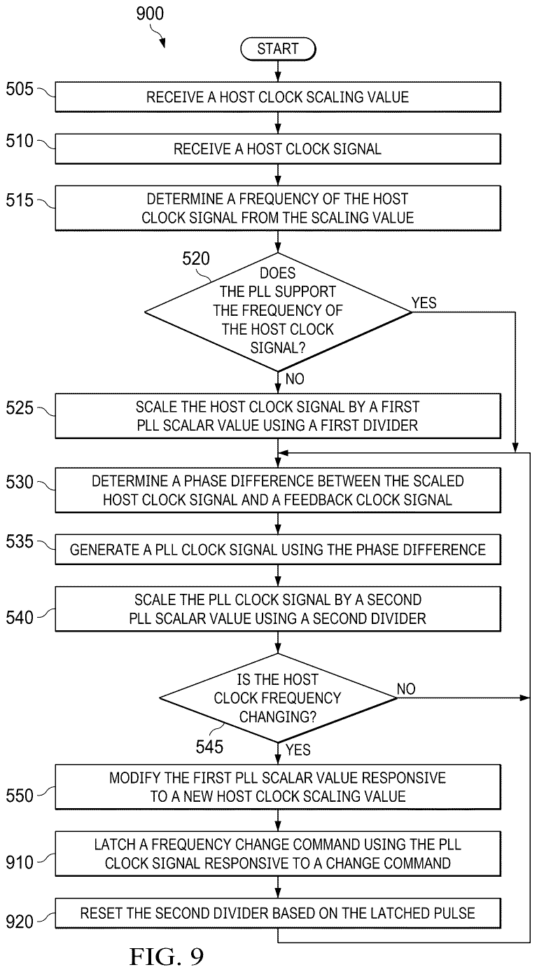

The signal processing circuitry 155 processes data from the analog circuitry 145 and the interface circuitry 150. In some examples, the signal processing circuitry 155 retimes signals using a PLL clock (PLL_CLK). In some such examples, the signal processing circuitry 155 may upscale signals using the PLL clock (PLL_CLK). The PLL circuitry 160 produces the PLL clock (PLL_CLK) based on the host clock (SW_CLK). The PLL circuitry 160 implements a phase lock loop to increase the frequency of the host clock (SW_CLK). Example implementations of the PLL circuitry 160 are further illustrated and described, e.g., in FIGS. 2, 3, and 7. Example operations of the PLL circuitry 160 are further illustrated and described, e.g., in connection with FIGS. 5 and 9. The digital circuitry 140 provides processed digital audio signals to the analog circuitry 145 and the host device 105.

The analog circuitry 145 of FIG. 1 includes DAC 165 and analog-to-digital converter (ADC) 170. The analog circuitry 145 receives the PLL clock (PLL_CLK), a digital audio signal from the digital circuitry 140, and an analog audio signal from the microphone 120. The DAC 165 converts the received digital audio signal to analog using the PLL clock (PLL_CLK) from the PLL circuitry 160. The DAC 165 provides the converted digital audio signal to the speaker 115. The ADC 170 converts the received analog audio signal to digital. The ADC 170 provides the converted digital audio signal to the digital circuitry 140. Advantageously, the PLL circuitry 160 can drive a wide range of functions of the audio system 100. Advantageously, improving the immunity of the PLL circuitry 160 to changes in the host clock (SW_CLK) reduces distortions in the DAC 165.

In the example of FIG. 1, the PLL circuitry 160 is illustrated and described in connection with the audio amplifier circuitry 110 or more generally in the audio system 100. Alternatively, in other examples, the PLL circuitry 160 may be illustrated and described in connection with other systems. For example, a communication system that uses a frequency hopping protocol may include the PLL circuitry 160 to account for on-the-fly frequency changes of a signal. In some examples, an encryption system that uses a frequency scrambling protocol may include the PLL circuitry 160 to account for on-the-fly frequency changes of an encrypted signal. Advantageously, the PLL circuitry 160 described herein may be implemented in a wide range of systems to provide a stable clock signal despite changing frequencies of a received signal.

FIG. 2 is a block diagram of an example implementation of the PLL circuitry 160 of FIG. 1, according to an embodiment of the present disclosure. The PLL circuitry 160 of FIG. 2 may be instantiated (e.g., creating an instance of, bring into being for any length of time, materialize, implement, etc.) by programmable circuitry such as a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the PLL circuitry 160 of FIG. 2 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 2 may, thus, be instantiated at the same or different times. Some or all of the circuitry of FIG. 2 may be instantiated, for example, in one or more threads executing concurrently on hardware or in series on hardware. Moreover, in some examples, some or all of the circuitry of FIG. 2 may be implemented by microprocessor circuitry executing instructions or FPGA circuitry performing operations to implement one or more virtual machines or containers. The example PLL circuitry 160 of FIG. 2 includes a first example divider circuitry 210, example phase frequency detector (PFD) circuitry 220, an example charge pump circuitry 230, an example loop filter circuitry 240, an example voltage-controlled oscillator (VCO) 250, a second example divider circuitry 260, a first example controller 270, and a second example controller 280.

In some embodiments, controllers 270 and 280 may be implemented as a single controller. In some embodiments, controllers 270 and/or 280 may be implemented as a generic or custom processor or controller coupled to a memory and configured to execute instructions in such memory. In some embodiments, controllers 270 and/or 280 may include a state machine and/or hardware accelerator. In some embodiments, controllers 270 and/or 280 may be implemented as part of an FPGA. Other implementations may also be possible.

The PLL circuitry 160 receives the host clock (SW_CLK), a frequency switch pulse (CMD(PREPARE_SWITCH)), and a scaling factor update (CMD(N′)). In some examples, the host device 105 provides the host clock (SW_CLK) in response to dividing a reference clock by the scaling factor (N). The frequency switch pulse (CMD(PREPARE_SWITCH)) represents a command from the host device 105 to prepare the PLL circuitry 160 for a change in frequency of the host clock (SW_CLK). In some examples, the frequency switch pulse (CMD(PREPARE_SWITCH)) is a signal indicating an on-the-fly change in the frequency between the interface circuitry 130, 150. The scaling factor update (CMD(N′)) represents a command from the host device 105 including an updated scaling factor (N′). The updated scaling factor (N′) corresponds to the scaling factor of the host device 105 after a change in frequency event.

The divider circuitry 210 (also referred to as clock divider or clock divider circuitry) receives the host clock (SW_CLK). The divider circuitry 210 divides the host clock (SW_CLK) by a first PLL scaling factor (J). In example operations, the divider circuitry 210 decrements a count for each cycle of the host clock (SW_CLK). In some such examples, the divider circuitry 210 produces a pulse responsive to the count being equal to zero. In some embodiments, the divider circuitry 210 may count cycles of the host clock (SW_CLK). In some such example operations, the divider circuitry 210 produces a pulse responsive to the count being equal to the first PLL scaling factor (J). In some examples, the divider circuitry 210 is illustrated as or described as a counter. In some example operations, the divider circuitry 210 divides the frequency of the host clock (SW_CLK) by the first PLL scaling factor (J). The divider circuitry 210 provides a reference clock (REF_CLK) to the PFD circuitry 220. In some examples, the divider circuitry 210 is instantiated by ASIC or programmable circuitry executing divider instructions to perform operations such as those represented by the flowcharts of FIGS. 5 and 9.

The PFD circuitry 220 receives the reference clock (REF_CLK) from the divider circuitry 210 and a feedback clock (FB_CLK) from the divider circuitry 260. Similar to the reference clock (REF_CLK), the feedback clock (FB_CLK) is a divided clock signal based on a second PLL scaling factor (D). The PFD circuitry 220 compares the phases of the reference clock (REF_CLK) and the feedback clock (FB_CLK). The PFD circuitry 220 produces a voltage using the phase difference between the reference clock (REF_CLK) and the feedback clock (FB_CLK). The PFD circuitry 220 provides the voltage to the charge pump circuitry 230. In some examples, the PFD circuitry 220 is instantiated by ASIC or programmable circuitry executing phase frequency detector instructions to perform operations such as those represented by the flowcharts of FIGS. 5 and 9.

The charge pump circuitry 230 receives the voltage from the PFD circuitry 220. The charge pump circuitry 230 converts the voltage from the PFD circuitry 220 to a control voltage. In some examples, the charge pump circuitry 230 sets the control voltage to a negative voltage (e.g., a voltage less than a common potential) to represent the PFD circuitry 220 detecting a positive phase shift. Similarly, the charge pump circuitry 230 sets the control voltage to a positive voltage (e.g., a voltage greater than the common potential) to represent the PFD circuitry 220 detecting a negative phase shift. Alternatively, the charge pump circuitry 230 may represent the detected phase shift of the PFD circuitry 220 using a different range of voltages to set the control voltage.

The loop filter circuitry 240 receives the control voltage from the charge pump circuitry 230. The loop filter circuitry 240 filters relatively high-frequency changes of the control voltage. For example, the loop filter circuitry 240 may be or include a low-pass resistor-capacitor filter. The loop filter circuitry 240 provides the filtered voltage to the VCO 250. Advantageously, the loop filter circuitry 240 increases the loop stability of the PLL circuitry 160 by reducing relatively high-frequency changes in the control voltage from the charge pump circuitry 230. In some examples, the charge pump circuitry 230 and the loop filter circuitry 240 are implemented by discrete analog circuitry, which may be integrated into a multi-chip module or as part of an ASIC.

The VCO 250 receives a filtered control voltage from the loop filter 240. The VCO 250 produces a PLL clock (PLL_CLK) responsive to the filtered control voltage from the loop filter 240. In example operations, the VCO 250 sets the frequency of the PLL clock (PLL_CLK) using the filtered control voltage from the PFD circuitry 220. In some examples, the VCO 250 is a discrete VCO, such as a transmission line VCO or tank-based oscillator. In other examples, the VCO 250 may be any type of linear or harmonic isolator. In yet some other examples, the VCO 250 is instantiated by ASIC or programmable circuitry executing voltage-controlled oscillator instructions to perform operations such as those represented by the flowcharts of FIGS. 5 and 9.

The divider circuitry 260 (also referred to as clock divider or clock divider circuitry) receives the PLL clock (PLL_CLK). The divider circuitry 260 divides the PLL clock (PLL_CLK) by the second PLL scaling factor (D). In example operations, the divider circuitry 260 decrements the count for each cycle of the PLL clock (PLL_CLK). In such examples, the divider circuitry 260 produces a pulse responsive to the count being equal to zero. Alternatively, the divider circuitry 260 may count cycles of the PLL clock (PLL_CLK). In such example operations, the divider circuitry 260 produces a pulse responsive to the count being equal to the second PLL scaling factor (D). In some examples, the divider circuitry 260 may be illustrated as or described as a counter. In some example operations, the divider circuitry 260 divides the frequency of the PLL clock (PLL_CLK) by the second PLL scaling factor (D). The divider circuitry 260 provides the feedback clock (FB_CLK) to the PFD circuitry 220. In some examples, the divider circuitry 260 is instantiated by ASIC or programmable circuitry executing divider instructions to perform operations such as those represented by the flowcharts of FIGS. 5 and 9.

The controller 270 receives the frequency switch pulse (CMD(PREPARE_SWITCH)) and the scaling factor update (CMD(N′)). The frequency switch pulse (CMD(PREPARE_SWITCH)) indicates a change to the frequency of the host clock (SW_CLK). In some examples, the frequency switch pulse (CMD(PREPARE_SWITCH)) is a pulse indicating a timing of a change in frequency of the host clock (SW_CLK). The scaling factor update (CMD(N′)) represents the updated frequency of the host clock (SW_CLK). In some examples, the scaling factor update (CMD(N′)) includes an updated scaling factor (N′) of the divider circuitry 135, which produces the host clock (SW_CLK). In example operations, the controller 270 receives the frequency switch pulse (CMD(PREPARE_SWITCH)) and the scaling factor update (CMD(N′)) from the host device 105.

The controller 270 controls the first PLL scaling factor (J) of the divider circuitry 210. In example operations, the controller 270 determines an updated PLL scaling factor (J′) responsive to the frequency switch pulse (CMD(PREPARE_SWITCH)) and a scaling factor update (CMD(N′)). The controller 270 determines the updated PLL scaling factor (J′) using the updated scaling factor (N′). In some examples, the controller 270 determines a scaling constant (K) using the first PLL scaling factor (J) (e.g., before the update), the scaling factor (N) of the divider circuitry 135 (e.g., before the update). The scaling constant (K) may be found using Equation (1). Also, using Equation (1), the controller circuitry 270 may determine the updated PLL scaling factor (J′) based on the scaling constant (K) and the updated scaling factor (N′) of the divider circuitry 135. In some examples, the controller 270 is instantiated by ASIC or programmable circuitry executing controller instructions to perform operations such as those represented by the flowcharts of FIGS. 5 and 9.

$$J * N = K = {J}^{′} * {N}^{′} \qquad Equation ( 1 )$$

The controller 280 controls the divider circuitry 260. In example operations, the controller 280 adjusts the second PLL scaling factor (D) between pulses of the feedback clock (FB_CLK) to divide the PLL clock (PLL_CLK) by a non-integer value. For example, the controller 280 switches the second PLL scaling factor (D) between nine and ten to divide the PLL clock (PLL_CLK) by a value between nine and ten (e.g., 9.1, 9.2, etc.). In some examples, the controller 280 changes the phase of the feedback clock (FB_CLK) responsive to a change in frequency of the host clock (SW_CLK). Examples of the controller circuitry 280 are further illustrated and described in connection with FIGS. 3 and 7. Advantageously, changing the phase of the feedback clock (FB_CLK) to match the phase of the reference clock (REF_CLK) reduces the change in frequency of the PLL clock (PLL_CLK) during a change in the host clock (SW_CLK). In some examples, the controller 280 is instantiated by ASIC or programmable circuitry executing controller instructions to perform operations such as those represented by the flowcharts of FIGS. 5 and 9.

FIG. 3 is a block diagram of example PLL circuitry 300, which is an example of the PLL circuitry 160 of FIGS. 1 and 2. The example PLL circuitry 300 of FIG. 3 includes the divider circuitry 210, 260, the PFD circuitry 220, the charge pump circuitry 230, the loop filter circuitry 240, the VCO 250, the controller 270, and another example controller 310. The controller 310 is an example implementation of the controller 280 of FIG. 2. The example controller 310 of FIG. 3 includes example quantization circuitry 320 and an example look-up table (LUT) 330. Example operations of the controller 310 are further illustrated and described in connection with FIG. 5. In some examples, the controller 310 implements a loop-aware locking mechanism, which reduces phase error between the reference signal (REF_CLK) and the feedback clock (FB_CLK). In such examples, the controller 310 uses an awareness of state of the divider circuitry 210 to align the phases of the reference signal (REF_CLK) and the feedback clock (FB_CLK). In some examples, the controller 310 adjusts the divider circuitry 260 to reduce phase-error by modifying the rising edge of the feedback clock (FB_CLK). Advantageously, aligning the phases of the reference signal (REF_CLK) and the feedback clock (FB_CLK) allows the PLL circuitry 300 to maintain a phase lock during a frequency change in the host clock (SW_CLK).

The quantization circuitry 320 receives the count of the divider circuitry 210 (J(n)) and the output of the PFD circuitry 220. The quantization circuitry 320 controls the divider circuitry 260 using the second PLL scaling factor (D) and the phase of the feedback clock (FB_CLK). For example, if the divider circuitry 260 is a counter, the quantization circuitry 320 may change the count to modify the phase of the feedback clock (FB_CLK). Also, the quantization circuitry 320 can change the frequency of the feedback clock (FB_CLK) by modifying the second PLL scaling factor (D). In example operations, the quantization circuitry 320 dynamically adjusts the second PLL scaling factor (D) to implement a non-integer scaling factor. For example, the quantization circuitry 320 sets the second PLL scaling factor (D) to nine for four pulses of the feedback clock (FB_CLK) and the second PLL scaling factor (D) to ten for six pulses of the feedback clock (FB_CLK). In such examples, the quantization circuitry 320 implements an effective second PLL scaling factor (D) of nine and six tenths. In some examples, the quantization circuitry 320 is instantiated by ASIC or programmable circuitry executing quantization instructions to perform operations such as those represented by the flowchart of FIG. 5.

The LUT 330 is a memory structure containing reference PLL scaling factors and phase adjustment data. For example, if the divider circuitry 260 is a counter, the LUT 330 contains reference count values corresponding to different frequencies of the PLL clock (PLL_CLK). The phase adjustment data represents the adjustment of a subsequent pulse of the feedback clock (FB_CLK) to match updates to the reference clock (REF_CLK). In some examples, if the divider circuitry 260 produces the feedback clock (FB_CLK) based on a count of cycles of the PLL clock (PLL_CLK), the phase adjustment data is a count of a number of cycles to modify the count of the divider circuitry 260. In such examples, the quantization circuitry 320 may use the count of the divider circuitry 210 (J(n)) as a reference for the LUT 330. For example, the LUT 330 may store the number of cycles to adjust the divider circuitry 260 (T) using the current count of the divider circuitry 210 (n) and a ratio of the frequency of the PLL clock (PLL_FREQ) (also referred to as a switching frequency) to the frequency of the host clock (SW_FREQ). In such examples, the LUT 330 stores values corresponding to potential values of Equation (2). Alternatively, the quantization circuitry 320 may compute the number of cycles to adjust the divider circuitry 260 (T) using Equation (2).

$$T = n * \frac{PLL\_FREQ}{SW\_FREQ} \qquad Equation ( 2 )$$

In example operations, the quantization circuitry 320 adjusts (e.g., increases or decreases) the count of the divider circuitry 260 to advance the timing of the subsequent pulse of the feedback clock (FB_CLK). In some such examples, the quantization circuitry 320 advances generation of a subsequent edge of the feedback clock (FB_CLK). Advantageously, in some embodiments, advancing the pulse of the feedback clock (FB_CLK) to match the updated edge of the reference clock (REF_CLK) reduces the phase difference of the PFD circuitry 220. Advantageously, in some embodiments, decreasing the phase difference of the PFD circuitry 220 reduces frequency variations in the PLL clock (PLL_CLK) during changes in frequency of the host clock (SW_CLK).

Although in the example of FIG. 3, the controller 310 uses counter values to represent the adjustments to the divider circuitry 260, in some examples, the controller 310 uses timing elements to adjust the divider circuitry 260. For example, Equation (2) may be used to determine the period of time between the subsequent edge of the reference clock (REF_CLK) as if a frequency change is not occurring. In such examples, the controller 310 may adjust the divider circuitry 260 by the determined period to align the feedback clock (FB_CLK) and reference clock (REF_CLK). Advantageously, in both examples, the controller 310 uses information of the divider circuitry 210 to update the divider circuitry 260 and maintain a phase lock.

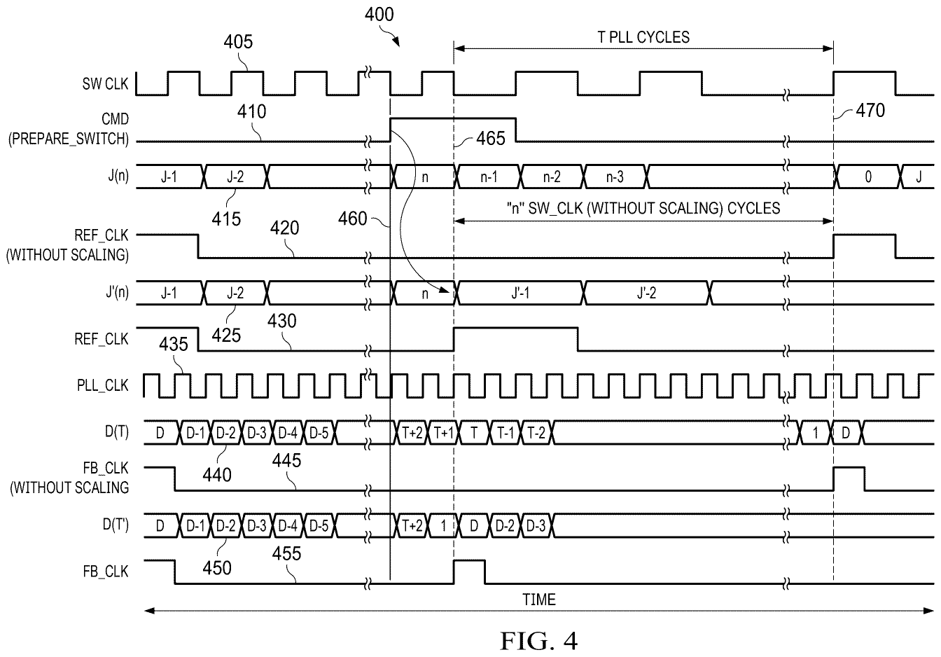

FIG. 4 is a timing diagram 400 of example operations of the controller 310 of FIG. 3 or more generally the PLL circuitry 160, 300 of FIGS. 1, 2, and 3, according to an embodiment of the present disclosure. In the example of FIG. 4, the timing diagram 400 illustrates a host clock 405 (SW_CLK), a frequency switch pulse 410 (CMD(PREPARE_SWITCH)), a first divider count 415 (J(n)), a reference clock 420 (REF_CLK (Without Scaling)), a first adjusted divider count 425 (J′ (n)), a reference clock 430 (REF_CLK), a PLL clock 435 (PLL_CLK), a second divider count 440 (D (T)), a feedback clock 445 (FB_CLK (Without Scaling)), a second adjusted divider count 450 (D (T′)), and a feedback clock 455 (FB_CLK).

The host clock 405 (e.g., a SoundWire clock) is a periodic clock signal provided by the host device 105. In some examples, such as in FIG. 1, the divider circuitry 135 produces the host clock 405 by dividing a signal from the oscillator 125. In example operations, the host device 105 communicates with the audio amplifier circuitry 110 using SoundWire protocols. In some such examples, Sound Wire protocols may change the frequency of the host clock 405 on-the-fly. For example, the change in the host clock 405 at the time 465.

The frequency switch pulse 410 represents a command from the host device 105 to prepare the PLL circuitry 160 for a change in frequency of the host clock 405. In the example of FIG. 4, the frequency switch pulse 410 is a pulse beginning at the time 460, approximately one cycle of the host clock 405 prior to the change in frequency. The PLL circuitry 160, 300 receives the frequency switch pulse 410 and the updated scaling factor prior to the change in frequency of the host clock 405 at the time 465.

The divider count 415 (J(n)) is a value of the divider circuitry 210 representing the number of cycles of the host clock 405 before another pulse of the reference clock 420. In the example of FIG. 4, the divider circuitry 210 is a counter, which counts down from the first PLL scalar value (J) using the host clock 405. In some such examples, the divider circuitry 210 produces a pulse of the reference clock 420 responsive to reaching zero. Unlike the adjusted divider count 425, the divider count 415 illustrates the count of the divider circuitry 210 without the frequency change at the time 465.

The reference clock 420 has a frequency approximately equal to the frequency of the host clock 405 divided by the first PLL scalar value (J) of the divider circuitry 210. The divider circuitry 210 produces the reference clock 420 using periodic pulses at the divided frequency of the host clock 405. Unlike the reference clock 430, the divider circuitry 210 produces the reference clock 420 without the frequency change at the time 465.

The adjusted divider count 425 is a value of the divider circuitry 210 representing the number of cycles of the host clock 405 before another pulse of the reference clock 430. Unlike the divider count 415, the adjusted divider count 425 illustrates the change in the first PLL scalar value (J) of the divider circuitry 210 to the updated PLL scalar value (J′). In some examples, the controller 270 uses Equation (1) to determine the updated PLL scalar value (J′). In such examples, the controller 270 changes the first PLL scalar value (J) a cycle of the host clock 405 after the frequency switch pulse 410 is set.

The reference clock 430 is the reference clock (REF_CLK) from the divider circuitry 210. Unlike the reference clock 420, the reference clock 430 illustrates the change in the reference clock (REF_CLK) from the divider circuitry 210 during a frequency change at the time 465. At the time 465, the controller 270 updates the first PLL scalar value (J) of the divider circuitry 210. The divider circuitry 210 produces the pulse at the time 465 responsive to the updated PLL scalar value (J′).

In some embodiments, the VCO 250 produces the PLL clock 435 as a periodic clock. The PFD circuitry 220 controls the frequency of the PLL clock 435 based on the phase difference between the reference clock 430 and the feedback clock 455. In example operation, the PLL circuitry 160, 300 compensates for the change in frequency of the host clock 405 without modifying the frequency of the PLL clock 435. Advantageously, as further described below, in some embodiments, adjusting the divider count 440 to the adjusted divider count 450 reduces the frequency variation of the PLL clock 435 by reducing the phase difference between the reference clock 430 and the feedback clock 455.

The divider count 440 is a value of the divider circuitry 260 representing the number of cycles of the PLL clock 435 before another pulse of the feedback clock 445. In the example of FIG. 4, the divider circuitry 260 is a counter, which counts down from the second PLL scalar value (D) using the PLL clock 435. In some such examples, the divider circuitry 260 produces a pulse of the feedback clock 445 responsive to reaching zero. Unlike the adjusted divider count 450, the divider count 440 illustrates the count of the divider circuitry 260 without the frequency change at the time 465.

In some embodiments, the feedback clock 445 has a frequency approximately equal to the frequency of the PLL clock 435 divided by the second PLL scalar value (D) of the divider circuitry 260. The divider circuitry 260 produces the feedback clock 445 using periodic pulses at the divided frequency of the PLL clock 435. Unlike the feedback clock 455, the divider circuitry 260 produces the feedback clock 445 without the frequency change at the time 465.

In some embodiments, the adjusted divider count 450 is a value of the divider circuitry 260 representing the number of cycles of the PLL clock 435 before another pulse of the feedback clock 455. Unlike the divider count 440, the adjusted divider count 450 illustrates modifying the count of the divider circuitry 260 by the number of cycles (T). In some examples, the controller 310 determines the number of cycles (T) to advance the divider count 440 to produce the adjusted divider count 450 using Equation (2). Unlike the divider circuitry 210, the quantization circuitry 320 decreases the count by the determined number of cycles (T) to advance the next pulse of the feedback clock 455. In such examples, the controller 310 changes the adjusted divider count 450 at approximately the same time as the controller 270 updates the first PLL scalar value. Advantageously, the determined number of cycles (T) represents the period between the time 465 and the time 470, which is approximately the time needed to advance the feedback clock 445.

In some embodiments, the feedback clock 455 is the feedback clock (FB_CLK) from the divider circuitry 260. Unlike the feedback clock 445, the feedback clock 455 illustrates the change in the feedback clock (FB_CLK) from the divider circuitry 260 during a frequency change at the time 465. At the time 465, the controller 310 adjusts the count of the divider circuitry 260 by the determined number of cycles (T). The divider circuitry 260 produces the pulse at the time 465 responsive to the adjusted count of the divider circuitry 260.

FIG. 5 is a flowchart representative of example machine-readable instructions or example operations 500 that may be at least one of executed, instantiated, or performed using an example implementation of the controller 280, 310 of FIGS. 2 and 3 or more generally the PLL circuitry 160, 300 of FIGS. 1, 2, and 3, according to an embodiment of the present disclosure. The example operations 500 begin at Block 505 at which the controller 270 receives a host clock scaling value. In example operations, the host device 105 provides a scaling factor update (CMD(N′)) representing the scaling factor of the divider circuitry 135. In some examples, the scaling factor update (CMD(N′)) is provided as part of the communication protocols communicatively coupling the host device 105 and the audio amplifier circuitry 110. For example, SoundWire protocols include commands indicating a change in the frequency of the host clock 405 (SW_CLK).

In some embodiments, the divider circuitry 210 receives a host clock signal. (Block 510). In example operations, the host device 105 produces the host clock 405 (SW_CLK) by dividing the output of the oscillator 125 by the scaling factor (N). The host device 105 provides the host clock 405 (SW_CLK) and the scaling factor (N) to the audio amplifier circuitry 110.

In some embodiments, the controller 270 determines a frequency of the host clock signal from the scaling value. (Block 515). In example operations, the controller 270 determines the frequency of the host clock 405 (SW_CLK) using the scaling factor (N). In some examples, the controller 270 is aware of the frequency of the oscillator 125 or references the scaling factor (N) to a data structure, such as a look-up table. In some such example operations, the controller 270 determines the scaling constant (K) of the divider circuitry 210 using the scaling factor (N). For example, the controller 270 may use Equation (1).

In some embodiments, the controller 270 determines if the PLL supports the frequency of the host clock signal. (Block 520). In some examples, the controller 270 determines if the divider circuitry 210 is needed based on the frequency of the host clock 405 (SW_CLK). In some examples, if the frequency of the host clock 405 (SW_CLK) is within a frequency range of the PLL circuitry 160, 300. For example, the controller 270 sets the first PLL scalar value (J) to one responsive to the frequency of the host clock 405 (SW_CLK) being supported by the loop formed between the PFD circuitry 220, the VCO 250, and the divider circuitry 260.

If the 250 determines that the PLL does not support the frequency of the host clock signal (e.g., Block 520 returns a result of NO), the divider circuitry 210 scales the host clock signal by a first PLL scalar value using a first divider. (Block 525). In example operation, the divider circuitry 210 scales the host clock 405 (SW_CLK) by the first PLL scalar value (J). For example, the divider circuitry 210 scales the host clock 405 (SW_CLK) to produce the reference clock 430 (REF_CLK). In such example operations, the frequency of the reference clock 430 (REF_CLK) is equal to the frequency of the host clock (SW_CLK) divided by the first PLL scalar factor (J).

If the controller 270 determines that the PLL does support the frequency of the host clock signal (e.g., Block 520 returns a result of YES) or control proceeds from Block 525, the PFD circuitry 220 determines a phase difference between the scaled host clock signal and a feedback clock signal. (Block 530). In example operations, the PFD circuitry 220 produces a voltage proportional to the difference between phases of the reference clock 430 (REF_CLK) and the feedback clock 455 (FB_CLK). Advantageously, the PFD circuitry 220 compensates for changes in the reference clock 430 (REF_CLK) or the feedback clock 455 (FB_CLK).

In some embodiments, the VCO 250 generates a PLL clock signal using the phase difference. (Block 535). In example operation, the VCO 250 produces the PLL clock 435 (PLL_CLK) responsive to the voltage from the PFD circuitry 220. In such example operations, the PFD circuitry 220 adjusts the frequency of the PLL clock 435 (PLL_CLK).

In some embodiments, the divider circuitry 260 scales the PLL clock signal by a second PLL scalar value using a second divider. (Block 540). In example operation, the divider circuitry 260 scales the PLL clock 435 (PLL_CLK) by the second PLL scalar value (D). For example, the divider circuitry 260 scales the PLL clock 435 (PLL_CLK) to produce the feedback clock 455 (FB_CLK). In such example operations, the frequency of the feedback clock 455 (FB_CLK) is equal to the frequency of the PLL clock 435 (PLL_CLK) divided by the second PLL scalar factor (D).

In some embodiments, the controller 270 determines if the host clock frequency is changing. (Block 545). In example operation, the host device 105 generates the frequency switch pulse 410 (CMD(PREPARE_SWITCH)) responsive to an on-the-fly change in frequency of the host clock 405 (SW_CLK). In some examples, the host device 105 starts the frequency switch pulse 410 (CMD(PREPARE_SWITCH)) one cycle of the host clock 405 (SW_CLK) prior to the frequency change. If the controller 270 determines that the host clock frequency is not changing (e.g., Block 545 returns a result of NO), control proceeds to return to Block 530.

If the controller 270 determines that the host clock frequency is changing (e.g., Block 545 returns a result of YES), the controller 270 modifies the first PLL scalar value responsive to a new host clock scaling value. (Block 550). In example operation, the host device 105 provides the scaling factor update (CMD(N′)) including the updated scaling factor of the divider circuitry 135 prior to a frequency change. In such example operations, the controller 270 determines the updated scalar value (J′) using Equation (1).

In some embodiments, the controller 310 determines a feedforward period based on the value of the count of the first divider, the frequency of the PLL, and the modified host clock frequency. (Block 555). In example operation, the controller 310 uses the current count of the divider circuitry 210 (J(n)), the updated host clock frequency (SW_FREQ), and the PLL clock frequency (PLL_FREQ) to determine a number of cycles to adjust the count of the divider circuitry 260 (T). In some examples, the LUT 330 stores reference adjustment values. In other examples, the quantization circuitry 320 calculates the adjustment. In both examples, Equation (2) may be used to determine the number of cycles of the PLL clock 435 (PLL_CLK) to adjust the divider circuitry 260.

The controller 310 advances the second divider using the feedforward period. (Block 560). In example operation, the quantization circuitry 320 modifies the divider count 440 to produce the adjusted divider count 450. In some examples, if the divider circuitry 260 is a counter, the quantization circuitry 320 increases or decreases the divider count 440. Advantageously, adjusting the divider circuitry 260 to produce an edge at approximately the same time as the controller 270 updates the first PLL scalar value (J) reduces the phase difference between the reference clock 430 and the feedback clock 455. Advantageously, the PFD circuitry 220 and the VCO 250 remain in a stable operating condition (also referred to as a phase lock) despite a change in the frequency of the host clock 405.

Control proceeds to return to Block 530. Example methods are described with reference to the flowchart illustrated in FIG. 5. However, many other methods of implementing the controller 280, 310 of FIGS. 2 and 3 or more generally the PLL circuitry 160, 300 of FIGS. 1, 2, and 3 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

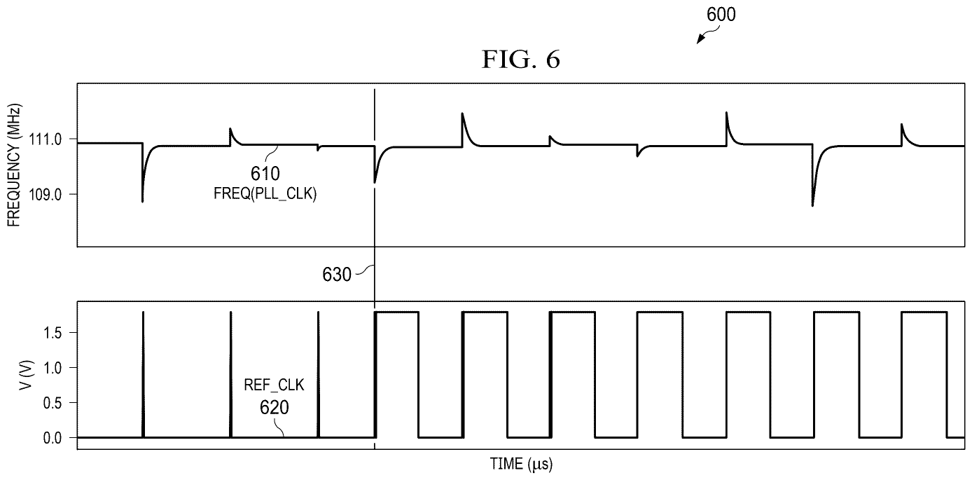

FIG. 6 is a timing diagram 600 of example operations of the PLL circuitry 160, 300 of FIGS. 1, 2, and 3 during an example frequency change, according to an embodiment of the present disclosure. In the example of FIG. 6, the timing diagram 600 illustrates an example PLL frequency 610 (FREQ(PLL_CLK)) and an example reference clock 620 (REF_CLK).

The PLL frequency 610 represents the frequency of the PLL clock 435 (PLL_CLK) from the VCO 250. Ideally, the frequency of the PLL clock 435 remains fixed despite changes in the frequency of the reference clock 620. The reference clock 620 is another example of the reference clock 430 during a frequency shift. Similar to the reference clock 430, the divider circuitry 210 generates the reference clock 620.

At a time 630, the controller 270 adjusts the divider circuitry 210 for a change in the frequency of the host clock 405 (SW_CLK). Advantageously, in some embodiments, the PLL frequency 610 remains relatively constant despite the change in the frequency of the reference clock 620. Advantageously, in some embodiments, adjusting the divider circuitry 260 using Equation (2) reduces changes to the PLL frequency 610.

FIG. 7 is a block diagram of example PLL circuitry 700, which is another example of the PLL circuitry 160, 300 of FIGS. 1, 2, and 3, according to an embodiment of the present disclosure. The example PLL circuitry 700 of FIG. 7 includes the divider circuitry 210, 260, the PFD circuitry 220, the charge pump circuitry 230, the loop filter circuitry 240, the VCO 250, the controller 270, and another example controller 710. The controller 710 is another example implementation of the controller 270 of FIG. 2. The controller 710 of FIG. 7 includes a first flip-flop 720, a second flip-flop 730, a third flip-flop 740, a fourth flip-flop 750, and a logic device 760. Unlike in the example of FIG. 3, the controller 710 of FIG. 7 implements a brute force locking mechanism to reduce phase-error between the reference clock (REF_CLK) and the feedback clock (FB_CLK). In example operations, the controller 710 latches the frequency switch pulse (CMD(PREPARE_SWITCH)) from the host device 105 using the PLL clock (PLL_CLK). In some such example operations, the controller 710 resets the count of the divider circuitry 260 based on the latched signal. Advantageously, in some embodiments, using the frequency switch pulse (CMD(PREPARE_SWITCH)) to reset the divider circuitry 260.

The flip-flops 720, latch the frequency switch 740 pulse (CMD(PREPARE_SWITCH)) based on at least one of the rising or falling edges of the PLL clock (PLL_CLK). The flip-flops 730, 750 latch respective ones of the outputs of the flip-flops 720, 740 based on at least one of the rising or falling edges of the PLL clock (PLL_CLK). In example operations, the flip-flops 720, 730, 740, 750 set an input of the logic device 760 in approximately one and a half cycles of the PLL clock (PLL_CLK). In the example of FIG. 7, the flip-flops 720, 730, 740, 750 are data flip-flops (D flip-flops) having a data input and a clock input. In some examples, the flip-flops are referred to as latch circuitry. Alternatively, in some embodiments, the flip-flops 720, 730, 740, 750 may be modified or replaced with an alternative type of flip-flop or latch mechanism.

The logic device 760 produces a reset pulse (RST_PULSE) responsive to the outputs of the flip-flops 730, 750. In example operation, the reset pulse (RST_PULSE) resets the count of the divider circuitry 260. In such example operations, the divider circuitry 260 produces a pulse on the feedback clock (FB_CLK) responsive to the reset pulse. In the example of FIG. 7, the logic device 760 is an OR gate. Alternatively, the logic device 760 may implement alternative logic.

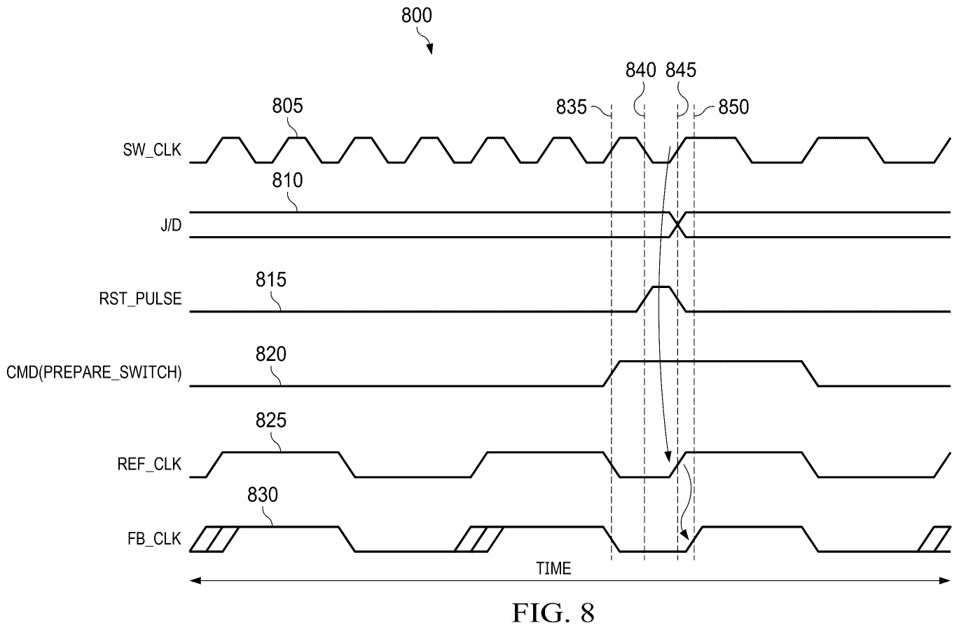

FIG. 8 is a timing diagram 800 of example operations of the controller 710 of FIG. 7 or more generally the PLL circuitry 160, 700 of FIGS. 1, 2, and 7, according to an embodiment of the present disclosure. In the example of FIG. 8, the timing diagram 800 illustrates an example host clock 805 (SW_CLK), an example divider count value 810 (J/D), an example reset pulse 815 (RST_PULSE), an example frequency switch pulse 820 (CMD(PREPARE_SWITCH)), an example reference clock signal 825 (REF_CLK), and an example feedback clock 830 (FB_CLK).

The host clock 805 is another example of the host clock 405. The host clock 805 (e.g., a SoundWire clock) is a periodic clock signal provided by the host device 105. In some examples, such as in FIG. 1, the divider circuitry 135 produces the host clock 805 by dividing a signal from the oscillator 125. In example operations, the host device 105 communicates with the audio amplifier circuitry 110 using SoundWire protocols. In such examples, SoundWire protocols may change the frequency of the host clock 805 on-the-fly. For example, the change in the host clock 805 at the time 845.

The divider count value 810 represents the counts of the divider circuitry 210, 260. At the time 845, the change in the divider count value 810 illustrates the reset of the count resulting from the controller 270 updating the first PLL scalar value (J). Also, at the time 845 the change in the divider count value 810 illustrates the reset of the count of the divider circuitry 210.

The logic device 760 produces reset pulse 815. Between the times 835 and 840, the flip-flops 720, 730, 740, 750 latch the rising edge of the frequency switch pulse 820.

The frequency switch pulse 820 is another example of the frequency switch pulse 410. The frequency switch pulse 820 represents a command from the host device 105 to prepare the PLL circuitry 160 for a change in frequency of the host clock 805. In the example of FIG. 8, the frequency switch pulse 820 is a pulse beginning at the time 835, approximately one cycle of the host clock 805 prior to the change in frequency. The PLL circuitry 160, 700 receives the frequency switch pulse 820 and the updated scaling factor prior to the change in frequency of the host clock 805 at the time 845.

The reference clock signal 825 is the reference clock (REF_CLK) from the divider circuitry 210. Unlike the reference clock 430 of FIG. 4, the divider circuitry 210 produces the reference clock 825 by producing a pulse having a fifty percent duty cycle. At the time 845, the controller 270 updates the first PLL scalar value (J) of the divider circuitry 210. The divider circuitry 210 produces the pulse at the time 845 responsive to the updated PLL scalar value (J′).

The feedback clock 830 is the feedback clock (FB_CLK) from the divider circuitry 260. Unlike the feedback clock 455 of FIG. 4, the divider circuitry 260 produces the feedback clock 830 by producing a pulse having a fifty percent duty cycle. At the time 850, the reset pulse 815 resets the divider circuitry 260. The divider circuitry 260 produces the pulse at the time 850 responsive to the reset pulse 815.

FIG. 9 is a flowchart representative of example machine-readable instructions or example operations 900 that may be at least one of executed, instantiated, or performed using an example implementation of the controller 280, 710 of FIGS. 2 and 7 or more generally the PLL circuitry 160, 700 of FIGS. 1, 2, and 7, according to an embodiment of the present disclosure. The example operations 900 begin with Blocks 505, 510, 515, 520, 525, 530, 535, 540, 545, 550 of the example operations 500 of FIG. 5. However, unlike in the example operations 500 of FIG. 5, control proceeds to Block 910.

The controller 710 latches a frequency change command using the PLL clock signal responsive to a change command. (Block 910). In example operations, the flip-flops 720, 740 latch the frequency switch pulse (CMD(PREPARE_SWITCH)) based on at least one of the rising or falling edges of the PLL clock (PLL_CLK) (e.g., the PLL clock 435). Similarly, the flip-flops 730, 750 latch the outputs of the flip-flops 720, 740 based on at least one of the rising or falling edges of the PLL clock (PLL_CLK). Advantageously, in some embodiments, the flip-flops 720, 730, 740, 750 produce a rising edge between half and one and a half cycles of the PLL clock after the rising edge of the frequency switch pulse (CMD(PREPARE_SWITCH)).

The controller 710 resets the second divider based on the latched pulse. (Block 920). In example operations, the logic device 760 provides the reset pulse 815 (RST_PULSE) to the divider circuitry 260. The divider circuitry 260 generates a rising edge on the feedback clock (FB_CLK) responsive to the reset. Advantageously, the rising edge of the feedback clock 830 (FB_CLK) is in proximity to the pulse of the reference clock 825 (REF_CLK). Advantageously, in some embodiments, such a proximity reduces the phase-error improves a likelihood of maintaining a phase lock.

Control proceeds to return to Block 530. Example methods are described with reference to the flowchart illustrated in FIG. 9. However, many other methods of implementing the controller 280, 710 of FIGS. 2 and 7 or more generally the PLL circuitry 160, 700 of FIGS. 1, 2, and 7 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

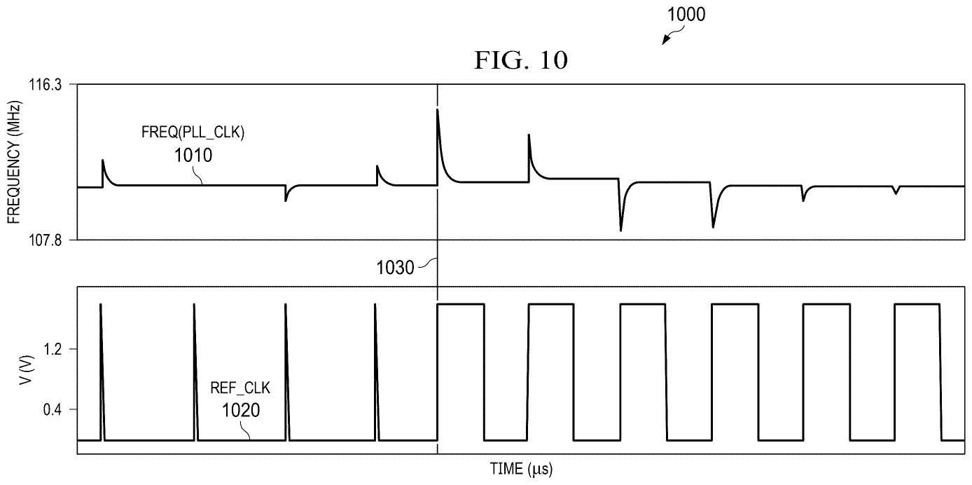

FIG. 10 is a timing diagram 1000 of example operations of the PLL circuitry 160, 700 of FIGS. 1, 2, and 7 during an example frequency change, according to an embodiment of the present disclosure. In the example of FIG. 10, the timing diagram 1000 illustrates an example PLL frequency 1010 (FREQ(PLL_CLK)) and an example reference clock 1020 (REF_CLK).

The PLL frequency 1010 represents the frequency of the PLL clock (PLL_CLK) from the VCO 250. Ideally, the frequency of the PLL clock (PLL_CLK) remains fixed despite changes in the frequency of the reference clock 1020. The reference clock 1020 is another example of the reference clock 825 during a frequency shift. Similar to the reference clock 825, the divider circuitry 210 produces the reference clock 1020.

At a time 1030, the controller 270 adjusts the divider circuitry 210 for a change in the frequency of the host clock 805 (SW_CLK). Advantageously, in some embodiments, the PLL frequency 1010 remains relatively constant despite the change in the frequency of the reference clock 1020. Advantageously, in some embodiments, resetting the divider circuitry 260 using the reset pulse 815 reduces changes to the PLL frequency 1010.

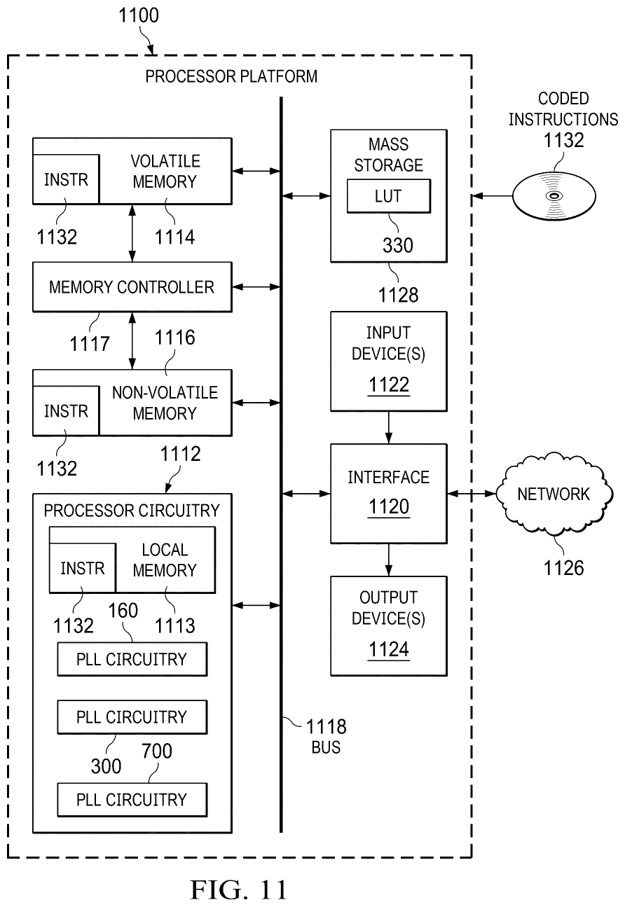

FIG. 11 is a block diagram of an example programmable circuitry platform 1100 structured to one or a combination of execute or instantiate one or more of the example machine-readable instructions or the example operations of FIGS. 5 and 9 to implement the PLL circuitry 160, 300, 700 of FIGS. 2, 3, and 7, according to an embodiment of the present disclosure. The programmable circuitry platform 1100 can be, for example, a server, a personal computer, a workstation, a self-learning machine (e.g., a neural network), a mobile device (e.g., a cell phone, a smart phone, a tablet), a personal digital assistant (PDA), an Internet appliance, a DVD player, a CD player, a digital video recorder, a Blu-ray player, a gaming console, a personal video recorder, a headset (e.g., an augmented reality (AR) headset, a virtual reality (VR) headset, etc.) or other wearable device, or any other type of computing or electronic device.

The programmable circuitry platform 1100 of the illustrated example includes programmable circuitry 1112. The programmable circuitry 1112 of the illustrated example is hardware. For example, the programmable circuitry 1112 can be implemented by one or more integrated circuits, logic circuits, FPGAs, microprocessors, CPUs, GPUs, DSPs, or microcontrollers from any desired family or manufacturer. The programmable circuitry 1112 may be implemented by one or more semiconductor based (e.g., silicon based) devices. In this example, the programmable circuitry 1112 implements one or more portions of the PLL circuitry 160, 300, 700.

The programmable circuitry 1112 of the illustrated example includes a local memory 1113 (e.g., a cache, registers, etc.). The programmable circuitry 1112 of the illustrated example is in communication with main memory 1114, 1116, which includes a volatile memory 1114 and a non-volatile memory 1116, by a bus 1118. The volatile memory 1114 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1116 may be implemented by one or a combination of flash memory or any other desired type of memory device. Access to the main memory 1114, 1116 of the illustrated example is controlled by a memory controller 1117. In some examples, the memory controller 1117 may be implemented by one or more integrated circuits, logic circuits, microcontrollers from any desired family or manufacturer, or any other type of circuitry to manage the flow of data going to and from the main memory 1114, 1116.

The programmable circuitry platform 1100 of the illustrated example also includes interface circuitry 1120. The interface circuitry 1120 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1122 are connected to the interface circuitry 1120. The input device(s) 1122 permit(s) a user (e.g., a human user, a machine user, etc.) to enter one of or a combination of data or commands into the programmable circuitry 1112. The input device(s) 1122 can be implemented by, for example, one of or a combination of an audio sensor, a microphone (e.g., the microphone 120 of FIG. 1), a camera (still or video), a keyboard, a button, a mouse, a touchscreen, a trackpad, a trackball, an isopoint device, or a voice recognition system.

One or more output devices 1124 are also connected to the interface circuitry 1120 of the illustrated example. The output device(s) 1124 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a printer, or speaker (e.g., the speaker 115 of FIG. 1). The interface circuitry 1120 of the illustrated example, thus, includes one of or a combination of a graphics driver card, a graphics driver chip, or graphics processor circuitry such as a GPU.

The interface circuitry 1120 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1126. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1100 of the illustrated example also includes one or more mass storage discs or devices 1128 to store one or more of firmware, software, or data. Examples of such mass storage discs or devices 1128 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1132, which may be implemented by the machine-readable instructions of FIGS. 5 and 9, may be stored in one of or a combination of the mass storage device 1128, in the volatile memory 1114, in the non-volatile memory 1116, or on at least one non-transitory computer readable storage medium such as a CD or DVD which may be removable.

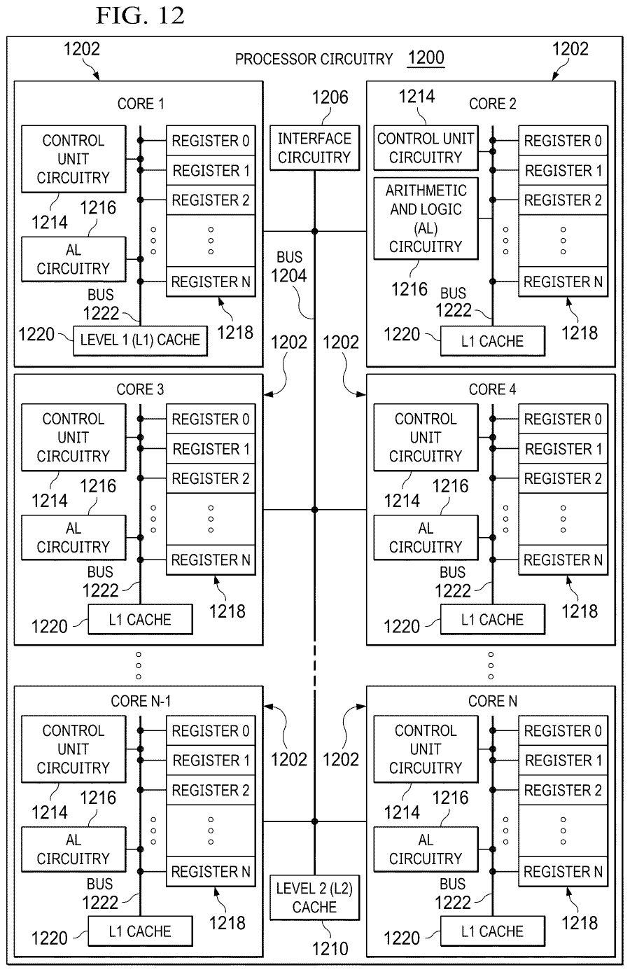

FIG. 12 is a block diagram of an example implementation of the programmable circuitry 1112 of FIG. 11. In this example, the programmable circuitry 1112 of FIG. 11 is implemented by a microprocessor 1200. For example, the microprocessor 1200 may be a general-purpose microprocessor (e.g., general-purpose microprocessor circuitry). The microprocessor 1200 executes some or all of the machine-readable instructions of the flowcharts of FIGS. 5 and 9 to effectively instantiate the circuitry of FIGS. 2, 3, and 7 as logic circuits to perform operations corresponding to those machine-readable instructions. In some such examples, the circuitry of FIGS. 2, 3, and 7 is instantiated by the hardware circuits of the microprocessor 1200 in combination with the machine-readable instructions. For example, the microprocessor 1200 may be implemented by multi-core hardware circuitry such as a CPU, a DSP, a GPU, an XPU, etc. Although it may include any number of example cores 1202 (e.g., 1 core), the microprocessor 1200 of this example is a multi-core semiconductor device including N cores. The cores 1202 of the microprocessor 1200 may operate independently or may cooperate to execute machine-readable instructions. For example, machine code corresponding to a firmware program, an embedded software program, or a software program may be executed by one of the cores 1202 or may be executed by multiple ones of the cores 1202 at the same or different times. In some examples, the machine code corresponding to the firmware program, the embedded software program, or the software program is split into threads and executed in parallel by two or more of the cores 1202. The software program may correspond to a portion or all of the machine-readable instructions or operations represented by the flowcharts of FIGS. 5 and 9.

The cores 1202 may communicate by a first example bus 1204. In some examples, the first bus 1204 may be implemented by a communication bus to effectuate communication associated with one(s) of the cores 1202. For example, the first bus 1204 may be implemented by at least one of an Inter-Integrated Circuit (I2C) bus, a Serial Peripheral Interface (SPI) bus, a PCI bus, or a PCIe bus. Also or alternatively, the first bus 1204 may be implemented by any other type of computing or electrical bus. The cores 1202 may receive data, instructions, and signals from one or more external devices by example interface circuitry 1206. The cores 1202 may output data, instructions, and signals to the one or more external devices by the interface circuitry 1206. Although the cores 1202 of this example include example local memory 1220 (e.g., Level 1 (L1) cache that may be split into an L1 data cache and an L1 instruction cache), the microprocessor 1200 also includes example shared memory 1210 that may be shared by the cores (e.g., Level 2 (L2 cache)) for high-speed access to data and instructions. Data and instructions may be transferred (e.g., shared) by one of or a combination of writing to or reading from the shared memory 1210. The local memory 1220 of each of the cores 1202 and the shared memory 1210 may be part of a hierarchy of storage devices including multiple levels of cache memory and the main memory (e.g., the main memory 1114, 1116 of FIG. 11). In some examples, higher levels of memory in the hierarchy exhibit lower access time and have smaller storage capacity than lower levels of memory. Changes in the various levels of the cache hierarchy are managed (e.g., coordinated) by a cache coherency policy.

Each core 1202 may be referred to as a CPU, DSP, GPU, etc., or any other type of hardware circuitry. Each core 1202 includes control unit circuitry 1214, arithmetic and logic (AL) circuitry (sometimes referred to as an ALU) 1216, a plurality of registers 1218, the local memory 1220, and a second example bus 1222. Other structures may be present. For example, each core 1202 may include vector unit circuitry, single instruction multiple data (SIMD) unit circuitry, load/store unit (LSU) circuitry, branch/jump unit circuitry, floating-point unit (FPU) circuitry, etc. The control unit circuitry 1214 includes semiconductor-based circuits structured to control (e.g., coordinate) data movement within the corresponding core 1202. The AL circuitry 1216 includes semiconductor-based circuits structured to perform one or more mathematic or logic operations on the data within the corresponding core 1202. The AL circuitry 1216 of some examples performs integer-based operations. In other examples, the AL circuitry 1216 also performs floating-point operations. In yet other examples, the AL circuitry 1216 may include first AL circuitry that performs integer-based operations and second AL circuitry that performs floating-point operations. In some examples, the AL circuitry 1216 may be referred to as an Arithmetic Logic Unit (ALU).

The registers 1218 are semiconductor-based structures to store data and instructions such as results of one or more of the operations performed by the AL circuitry 1216 of the corresponding core 1202. For example, the registers 1218 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1218 may be arranged in a bank as shown in FIG. 12. Alternatively, the registers 1218 may be organized in any other arrangement, format, or structure, such as by being distributed throughout the core 1202 to shorten access time. The second bus 1222 may be implemented by at least one of an I2C bus, a SPI bus, a PCI bus, or a PCIe bus.

Each core 1202 or, more generally, the microprocessor 1200 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1200 is a semiconductor device fabricated to include many transistors interconnected to implement the structures described above in one or more integrated circuits (ICs) contained in one or more packages.

The microprocessor 1200 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those described herein. A GPU, DSP, or other programmable device can also be an accelerator. Accelerators may be on-board the microprocessor 1200, in the same chip package as the microprocessor 1200, or in one or more separate packages from the microprocessor 1200.

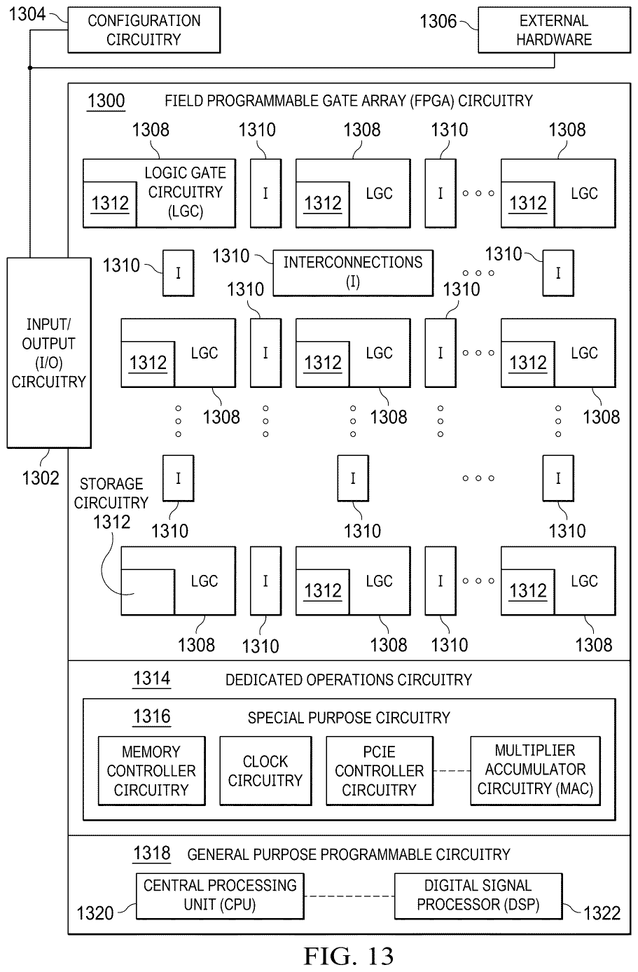

FIG. 13 is a block diagram of another example implementation of the programmable circuitry 1112 of FIG. 11. In this example, the programmable circuitry 1112 is implemented by FPGA circuitry 1300. For example, the FPGA circuitry 1300 may be implemented by an FPGA. The FPGA circuitry 1300 can be used, for example, to perform operations that could otherwise be performed by the example microprocessor 1200 of FIG. 12 executing corresponding machine-readable instructions. However, once configured, the FPGA circuitry 1300 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1200 of FIG. 12 described above (which is a general purpose device that may be programmed to execute some or all of the machine-readable instructions represented by the flowchart(s) of FIGS. 5 and 9 but whose interconnections and logic circuitry are fixed once fabricated), the FPGA circuitry 1300 of the example of FIG. 13 includes interconnections and logic circuitry that may be one of or a combination of configured, structured, programmed, and interconnected in different ways after fabrication to instantiate, for example, some or all of the operations/functions corresponding to the machine-readable instructions represented by the flowchart(s) of FIGS. 5 and 9. In particular, the FPGA circuitry 1300 may be thought of as an array of logic gates, interconnections, and switches. The switches can be programmed to change how the logic gates are interconnected by the interconnections, effectively forming one or more dedicated logic circuits (unless and until the FPGA circuitry 1300 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 5 and 9. As such, the FPGA circuitry 1300 may be at least one of configured or structured to effectively instantiate some or all of the operations/functions corresponding to the machine-readable instructions of the flowchart(s) of FIGS. 5 and 9 as dedicated logic circuits to perform the operations/functions corresponding to those software instructions in a dedicated manner analogous to an ASIC. Therefore, the FPGA circuitry 1300 may perform the operations/functions corresponding to the some or all of the machine-readable instructions of FIGS. 5 and 9 faster than the general-purpose microprocessor can execute the same.

In the example of FIG. 13, the FPGA circuitry 1300 is at least one of configured or structured in response to being programmed (and/or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1300 of FIG. 13 may at least one of access or load the binary file to cause the FPGA circuitry 1300 of FIG. 13 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1300 of FIG. 13 to at least one of configure or structure the FPGA circuitry 1300 of FIG. 13, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1300 of FIG. 13 may at least one of access or load the binary file to cause the FPGA circuitry 1300 of FIG. 13 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1300 of FIG. 13 to at least one of configure or structure the FPGA circuitry 1300 of FIG. 13, or portion(s) thereof.

The FPGA circuitry 1300 of FIG. 13, includes example input/output (I/O) circuitry 1302 to at least one of receive or output data to/from at least one of example configuration circuitry 1304 or external hardware 1306. For example, the configuration circuitry 1304 may be implemented by interface circuitry that may receive a binary file, which may be implemented by one or more of a bit stream, data, or machine-readable instructions, to configure the FPGA circuitry 1300, or portion(s) thereof. In some such examples, the configuration circuitry 1304 may receive the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1306 may be implemented by external hardware circuitry. For example, the external hardware 1306 may be implemented by the microprocessor 1200 of FIG. 12.

The FPGA circuitry 1300 also includes an array of example logic gate circuitry 1308, a plurality of example configurable interconnections 1310, and example storage circuitry 1312. The logic gate circuitry 1308 and the configurable interconnections 1310 are configurable to instantiate one or more operations/functions that may correspond to at least some of the machine-readable instructions of FIGS. 5 and 9 and/or other desired operations. The logic gate circuitry 1308 shown in FIG. 13 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1308 to enable configuration of one of or a combination of the electrical structures or the logic gates to form circuits to perform desired operations/functions. The logic gate circuitry 1308 may include other electrical structures such as look-up tables (LUTs), registers (e.g., flip-flops or latches), multiplexers, etc.

The configurable interconnections 1310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1308 to program desired logic circuits.

The storage circuitry 1312 of the illustrated example is structured to store result(s) of the one or more of the operations performed by corresponding logic gates. The storage circuitry 1312 may be implemented by registers or the like. In the illustrated example, the storage circuitry 1312 is distributed amongst the logic gate circuitry 1308 to facilitate access and increase execution speed.

The example FPGA circuitry 1300 of FIG. 13 also includes example dedicated operations circuitry 1314. In this example, the dedicated operations circuitry 1314 includes special purpose circuitry 1316 that may be invoked to implement commonly used functions to avoid the need to program those functions in the field. Examples of such special purpose circuitry 1316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1300 may also include example general purpose programmable circuitry 1318 such as an example CPU 1320 or an example DSP 1322. Other general purpose programmable circuitry 1318 may also or alternatively be present such as a GPU, an XPU, etc., that can be programmed to perform other operations.

Although FIGS. 12 and 13 illustrate two example implementations of the programmable circuitry 1112 of FIG. 11, many other approaches are contemplated. For example, FPGA circuitry may include an on-board CPU, such as one or more of the example CPU 1320 of FIG. 12. Therefore, the programmable circuitry 1112 of FIG. 11 may also be implemented by combining at least the example microprocessor 1200 of FIG. 12 and the example FPGA circuitry 1300 of FIG. 13. In some such hybrid examples, one or more cores 1202 of FIG. 12 may execute a first portion of the machine-readable instructions represented by the flowchart(s) of FIGS. 5 and 9 to perform first operation(s)/function(s), the FPGA circuitry 1300 of FIG. 13 may be at least one of configured or structured to perform second operation(s)/function(s) corresponding to a second portion of the machine-readable instructions represented by the flowcharts of FIGS. 5 and 9, and/or an ASIC may be at least one of configured or structured to perform third operation(s)/function(s) corresponding to a third portion of the machine-readable instructions represented by the flowcharts of FIGS. 5 and 9.

Some or all of the circuitry of FIGS. 2, 3, and 7 may, thus, be instantiated at the same or different times. For example, same and/or different portion(s) of the microprocessor 1200 of FIG. 12 may be programmed to execute portion(s) of machine-readable instructions at the same and/or different times. In some examples, same and/or different portion(s) of the FPGA circuitry 1300 of FIG. 13 may be at least one of configured or structured to perform operations/functions corresponding to portion(s) of machine-readable instructions at the same and/or different times.

In some examples, some or all of the circuitry of FIGS. 2, 3, and 7 may be instantiated, for example, in one or more threads executing concurrently and/or in series. For example, the microprocessor 1200 of FIG. 12 may execute machine-readable instructions in one or more threads executing concurrently and/or in series. In some examples, the FPGA circuitry 1300 of FIG. 13 may be at least one of configured or structured to carry out operations/functions concurrently and/or in series. Moreover, in some examples, some or all of the circuitry of FIGS. 2, 3, and 7 may be implemented within one or more virtual machines or containers executing on the microprocessor 1200 of FIG. 12.

In some examples, the programmable circuitry 1112 of FIG. 11 may be in one or more packages. For example, at least one of the microprocessor 1200 of FIG. 12 or the FPGA circuitry 1300 of FIG. 13 may be in one or more packages. In some examples, an XPU may be implemented by the programmable circuitry 1112 of FIG. 11, which may be in one or more packages. For example, the XPU may include a CPU (e.g., the microprocessor 1200 of FIG. 12, the CPU 1320 of FIG. 13, etc.) in one package, a DSP (e.g., the DSP 1322 of FIG. 13) in another package, a GPU in yet another package, and an FPGA (e.g., the FPGA circuitry 1300 of FIG. 13) in still yet another package.

While an example manner of implementing the PLL circuitry 160, 300, 700 are illustrated in FIGS. 2, 3, and 7, one or more of the elements, processes, or devices illustrated in FIGS. 2, 3, and 7 may be combined, divided, re-arranged, omitted, eliminated, or implemented in any other way. Further, one or more portions of the example PLL circuitry 160, 300, 700 of FIGS. 2, 3, and 7, may be implemented by hardware alone or by hardware in combination with software and firmware. Thus, for example, any of the example PLL circuitry 160, 300, 700, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example PLL circuitry 160, 300, 700 of FIGS. 2, 3, and 7 may include one or more elements, processes, or devices in addition to, or instead of, those illustrated in FIGS. 2, 3, and 7, or may include more than one of any or all of the illustrated elements, processes and devices.

Flowchart(s) representative of example machine-readable instructions, which may be executed by programmable circuitry to at least one of implement or instantiate the PLL circuitry 160, 300, 700 of FIGS. 2, 3, and 7 or representative of example operations which may be performed by programmable circuitry to at least one of implement or instantiate the PLL circuitry 160, 300, 700 of FIGS. 2, 3, and 7, are shown in FIGS. 5 and 9. The machine-readable instructions may be one or more executable programs or portion(s) of one or more executable programs for execution by programmable circuitry such as the programmable circuitry 1112 shown in the example processor platform 1100 described below in connection with FIG. 11 and may be one or more function(s) or portion(s) of functions to be performed by the example programmable circuitry (e.g., an FPGA) described below in connection with FIG. 12 or 13. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 5 and 9, many other methods of implementing the example PLL circuitry 160, 300, 700 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs and/or one or more FPGAs located in the same package (e.g., the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., or any combination(s) thereof in any of the contexts described above.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order for them to be directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 5 and 9 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” may be understood to include (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry may be understood as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example embodiments of the present disclosure are summarized here. Other embodiments can also be understood from the entirety of the specification and the claims filed herein.

Example 1. A device including: phase frequency detector (PFD) circuitry having an input and an output; an oscillator having an input and an output, the input of the oscillator coupled to the output of the PFD circuitry; clock divider circuitry having a first input, a second input, and an output, the first input of the clock divider circuitry coupled to the output of the oscillator, the output of the clock divider circuitry coupled to the input of the PFD circuitry; and a controller having an output coupled to the second input of the clock divider circuitry.

Example 2. The device of example 1, where the oscillator is a voltage-controlled oscillator.

Example 3. The device of one of examples 1 or 2, where the clock divider circuitry includes a look up table having an output coupled to the second input of the clock divider circuitry.

Example 4. The device of one of examples 1 to 3, where the clock divider circuitry includes quantization circuitry having an input and an output, the output of the quantization circuitry coupled to the second input of the clock divider circuitry, and the input of the quantization circuitry coupled to the look up table.

Example 5. The device of one of examples 1 to 4, where the clock divider circuitry is first divider circuitry, the input of the quantization circuitry is a first input, the quantization circuitry further having a second input and a third input, the second input of the quantization circuitry coupled to the output of the PFD circuitry, and the device further including second divider circuitry having an output coupled to the third input of the quantization circuitry.

Example 6. The device of one of examples 1 to 5, where the controller includes: first latch circuitry having a first input, a second input, and an output; second latch circuitry having a first input, a second input, and an output, the first input of the second latch circuitry coupled to the first input of the first latch circuitry, the second input of the second latch circuitry coupled to the output of the oscillator and the first input of the clock divider circuitry; and logic circuitry having a first input, a second input, and an output, the first input of the logic circuitry coupled to the output of the first latch circuitry, the second input of the logic circuitry coupled to the output of the second latch circuitry, the output of the logic circuitry coupled to the second input of the clock divider circuitry.

Example 7. The device of one of examples 1 to 6, where the first latch circuitry includes: a first flip-flop having a data input, a clock input, and an output, the data input of the first flip-flop coupled to the first input of the second latch circuitry; and a second flip-flop having a data input, a clock input, and an output, the data input of the second flip-flop is coupled to the output of the first flip-flop, the clock input of the second flip-flop is coupled to the output of the oscillator, the first input of the clock divider circuitry, the second input of the second latch circuitry, and the clock input of the first flip-flop, and the output of the second flip-flop coupled to the first input of the logic circuitry.

Example 8. The device of one of examples 1 to 7, where the input of the PFD circuitry is a first input, the PFD circuitry further having a second input, the clock divider circuitry is first clock divider circuitry, and the device further including second clock divider circuitry having an output coupled to the second input of the PFD circuitry.

Example 9. The device of one of examples 1 to 8, where the controller is coupled to the second clock divider circuitry.

Example 10. The device of one of examples 1 to 9, where the input of the second clock divider circuitry is a first input, the second clock divider circuitry further has a second input, and the device further including: interface circuitry having a first input, a second input, and an output, the first input of the interface circuitry coupled to the controller, the second input of the interface circuitry coupled to the second input of the second clock divider circuitry; signal processing circuitry having an input and an output, the input of the signal processing circuitry coupled to the output of the interface circuitry; and analog circuitry having a first input and a second input, the first input of the analog circuitry coupled to the output of the oscillator and the first input of the first clock divider circuitry, the second input of the analog circuitry coupled to the output of the signal processing circuitry.

Example 11. The device of one of examples 1 to 10, further including a phase-locked loop (PLL) that includes the PFD, the oscillator, and the clock divider circuitry, and an output coupled to the output of the oscillator, the device further including a digital to analog converter (DAC) having a clock input coupled to the output of the PLL.

Example 12. The device of one of examples 1 to 11, further including a speaker coupled to an output of the DAC.

Example 13. The device of one of examples 1 to 12, further including a microphone, and an analog to digital converter (ADC) having an input coupled to the microphone.

Example 14. A device including: phase frequency detector (PFD) circuitry; an oscillator coupled to the PFD circuitry; clock divider circuitry having an output coupled to the PFD circuitry, and an input coupled to the oscillator; and a controller coupled to the clock divider circuitry, and configured to adjust the clock divider circuitry responsive to a change in a reference clock.

Example 15. The device of example 14, where the controller is further configured to advance a subsequent edge of a feedback clock from the clock divider circuitry to match a subsequent edge of the reference clock.

Example 16. The device of one of examples 14 or 15, where the controller is further configured to: latch a frequency switch pulse using a phase-locked loop (PLL) clock; and reset the clock divider circuitry responsive to latching the frequency switch pulse.

Example 17. The device of one of examples 14 to 16, where the frequency switch pulse is a command according to a SoundWire protocol.

Example 18. The device of one of examples 14 to 17, where the controller is further configured to maintain a frequency of a phase lock loop clock responsive to adjusting the clock divider circuitry.

Example 19. The device of one of examples 14 to 18, where the clock divider circuitry is first clock divider circuitry, the device further including second clock divider circuitry coupled to the PFD circuitry, the second clock divider circuitry configured to divide a host clock by a value to generate the reference clock, where the controller is configured to modify the value of the second clock divider circuitry responsive to a frequency switch pulse.

Example 20. The device of one of examples 14 to 19, where the controller is configured to: determine a number of cycles of a phase lock loop (PLL) clock to adjust the clock divider circuitry using a frequency of a host clock; and align a phase of the reference clock and a feedback clock signal using the number of cycles of the PLL clock.

Example 21. The device of one of examples 14 to 20, where the reference clock is a reference clock of a SoundWire interface.

Example 22. A method including: generating phase lock loop (PLL) clock based on a phase error between a reference clock and a feedback clock; dividing the PLL clock to generate the feedback clock; and adjusting a phase of the feedback clock responsive to a change in a frequency of the reference clock.

Example 23. The method of example 22, where adjusting the phase of the feedback clock includes advancing generation of a rising edge of the feedback clock to match a rising edge of the reference clock.

Example 24. The method of one of examples 22 or 23, further including determining a number of periods of the PLL clock to advance the rising edge of the feedback clock based on a frequency of the PLL clock and the frequency of the reference clock.

Example 25. The method of one of examples 22 to 24, where adjusting the phase of the feedback clock includes matching a rising edge of the reference clock with a rising edge of the feedback clock by resetting a clock divider.

Example 26. The method of one of examples 22 to 25, further including: latching a frequency switch pulse using the PLL clock; and resetting the clock divider based on the latching of the frequency switch pulse.

Example 27. The method of one of examples 22 to 26, further including: generating the reference clock by dividing a host clock by a value; and modifying the value responsive to the change in frequency of the reference clock.

Example 28. The method of one of examples 22 to 27, where adjusting the phase of the feedback clock includes determining a number of cycles of the PLL clock to advance the feedback clock using the number of cycles.

Example 29. The method of one of examples 22 to 28, further including generating a host clock in accordance with a SoundWire protocol.

Example 30. The method of one of examples 22 to 29, further including generating a host clock in accordance at least one of a frequency hopping protocol or a frequency scrambling protocol.

Example 31. The method of one of examples 22 to 30, further including: providing, by a host device, a host clock to an audio amplifier that includes the PLL; and providing, by the host device, a command to the audio amplifier, the command being indicative of a change in the frequency of the host clock and the reference clock.

Example 32. The method of one of examples 22 to 31, where the reference clock has a first frequency that is higher than a second frequency of a host clock signal.

Example 33. A method including: generating phase lock loop (PLL) clock based on a phase error between a reference clock and a feedback clock; dividing the PLL clock to generate the feedback clock; and adjusting the feedback clock responsive to a change in a frequency of the reference clock to maintain a switching frequency and phase of the PLL clock.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. A device comprising:
phase frequency detector (PFD) circuitry having an input and an output;
an oscillator having an input and an output, the input of the oscillator coupled to the output of the PFD circuitry;
clock divider circuitry having a first input, a second input, and an output, the first input of the clock divider circuitry coupled to the output of the oscillator, the output of the clock divider circuitry coupled to the input of the PFD circuitry; and
a controller having an output coupled to the second input of the clock divider circuitry.

2. The device of claim 1, wherein the oscillator is a voltage-controlled oscillator.

3. The device of claim 1, wherein the clock divider circuitry includes a look up table having an output coupled to the second input of the clock divider circuitry.

4. The device of claim 3, wherein the clock divider circuitry includes quantization circuitry having an input and an output, the output of the quantization circuitry coupled to the second input of the clock divider circuitry, and the input of the quantization circuitry coupled to the look up table.

5. The device of claim 4, wherein the clock divider circuitry is first divider circuitry, the input of the quantization circuitry is a first input, the quantization circuitry further having a second input and a third input, the second input of the quantization circuitry coupled to the output of the PFD circuitry, and the device further comprising second divider circuitry having an output coupled to the third input of the quantization circuitry.

6. The device of claim 1, wherein the controller includes:
first latch circuitry having a first input, a second input, and an output;
second latch circuitry having a first input, a second input, and an output, the first input of the second latch circuitry coupled to the first input of the first latch circuitry, the second input of the second latch circuitry coupled to the output of the oscillator and the first input of the clock divider circuitry; and
logic circuitry having a first input, a second input, and an output, the first input of the logic circuitry coupled to the output of the first latch circuitry, the second input of the logic circuitry coupled to the output of the second latch circuitry, the output of the logic circuitry coupled to the second input of the clock divider circuitry.

7. The device of claim 6, wherein the first latch circuitry includes:
a first flip-flop having a data input, a clock input, and an output, the data input of the first flip-flop coupled to the first input of the second latch circuitry; and
a second flip-flop having a data input, a clock input, and an output, the data input of the second flip-flop is coupled to the output of the first flip-flop, the clock input of the second flip-flop is coupled to the output of the oscillator, the first input of the clock divider circuitry, the second input of the second latch circuitry, and the clock input of the first flip-flop, and the output of the second flip-flop coupled to the first input of the logic circuitry.

8. The device of claim 1, wherein the input of the PFD circuitry is a first input, the PFD circuitry further having a second input, the clock divider circuitry is first clock divider circuitry, and the device further comprising second clock divider circuitry having an output coupled to the second input of the PFD circuitry.

9. The device of claim 8, wherein the controller is coupled to the second clock divider circuitry.

10. The device of claim 9, wherein the input of the second clock divider circuitry is a first input, the second clock divider circuitry further has a second input, and the device further comprising:
interface circuitry having a first input, a second input, and an output, the first input of the interface circuitry coupled to the controller, the second input of the interface circuitry coupled to the second input of the second clock divider circuitry;
signal processing circuitry having an input and an output, the input of the signal processing circuitry coupled to the output of the interface circuitry; and
analog circuitry having a first input and a second input, the first input of the analog circuitry coupled to the output of the oscillator and the first input of the first clock divider circuitry, the second input of the analog circuitry coupled to the output of the signal processing circuitry.

11. The device of claim 1, further comprising a phase-locked loop (PLL) that comprises the PFD, the oscillator, and the clock divider circuitry, and an output coupled to the output of the oscillator, the device further comprising a digital to analog converter (DAC) having a clock input coupled to the output of the PLL.

12. The device of claim 11, further comprising a speaker coupled to an output of the DAC.

13. The device of claim 12, further comprising a microphone, and an analog to digital converter (ADC) having an input coupled to the microphone.

14. A device comprising:
phase frequency detector (PFD) circuitry;
an oscillator coupled to the PFD circuitry;
clock divider circuitry having an output coupled to the PFD circuitry, and an input coupled to the oscillator; and
a controller coupled to the clock divider circuitry, and configured to adjust the clock divider circuitry responsive to a change in a reference clock.

15. The device of claim 14, wherein the controller is further configured to advance a subsequent edge of a feedback clock from the clock divider circuitry to match a subsequent edge of the reference clock.

16. The device of claim 14, wherein the controller is further configured to:
latch a frequency switch pulse using a phase-locked loop (PLL) clock; and
reset the clock divider circuitry responsive to latching the frequency switch pulse.

17. The device of claim 16, wherein the frequency switch pulse is a command according to a SoundWire protocol.

18. The device of claim 14, wherein the controller is further configured to maintain a frequency of a phase lock loop clock responsive to adjusting the clock divider circuitry.

19. The device of claim 14, wherein the clock divider circuitry is first clock divider circuitry, the device further comprising second clock divider circuitry coupled to the PFD circuitry, the second clock divider circuitry configured to divide a host clock by a value to generate the reference clock, wherein the controller is configured to modify the value of the second clock divider circuitry responsive to a frequency switch pulse.

20. The device of claim 14, wherein the controller is configured to:
determine a number of cycles of a phase lock loop (PLL) clock to adjust the clock divider circuitry using a frequency of a host clock; and
align a phase of the reference clock and a feedback clock signal using the number of cycles of the PLL clock.

21. The device of claim 14, wherein the reference clock is a reference clock of a SoundWire interface.
